(19) United States
(12) Patent Application Publication
(10) Pub. No.: US 2026/0052714 A1
(43) Pub. Date: Feb. 19, 2026

(54) SILICON CARBIDE LATERAL POWER SEMICONDUCTOR DEVICE

(71) Applicant: The University of Warwick, West Midlands (GB)

(72) Inventors: Peter GAMMON, West Midlands (GB); Marina ANTONIOU, West Midlands (GB); Yunyi QI, West Midlands (GB); Ben RENZ, West Midlands (GB)

(73) Assignee: The University of Warwick, West Midlands (GB)

(21) Appl. No.: 19/109,629

(22) PCT Filed: Aug. 30, 2023
(86) PCT No.: PCT/GB2023/052240

§ 371 Date: Mar. 7, 2025

(30) Foreign Application Priority Data
Sep. 9, 2022 (GB) 2213240.1

(51) Int. Cl. H10D 8/60; H10D 8/50; H10D 12/00; H10D 30/65; H10D 62/10; H10D 62/60; H10D 62/832; H10D 64/00

(52) U.S. Cl. CPC H10D 8/60; H10D 8/50; H10D 12/415; H10D 30/655; H10D 62/111; H10D 62/60; H10D 62/8325; H10D 64/112

(57) ABSTRACT

A lateral silicon carbide power semiconductor device is disclosed. The device comprises a substrate and a silicon carbide semiconductor structure disposed on the substrate and having a principal surface. The semiconductor structure comprises a layer of first conductivity type disposed on the substrate, and a layer-shaped drift region of a second conductivity type, which is opposite to the first conductivity type, disposed directly on the layer so as to form an interface between the layer and the drift region. The drift region runs laterally along the principal surface between first and second ends. Doping in the drift region and the layer are arranged so as to deplete the drift region. The device comprises a first contact region to the drift region. The device comprises a second contact region to the second end of the drift region which is highly doped, which is of the first or second conductivity type which adjoins the second end of the drift region, is disposed in the drift region or in a region which adjoins the second end of the drift region The device comprises a highly-doped region of the first conductivity type extending into the semiconductor structure from the principal surface and adjoining the first end of the drift region, wherein the highly-doped region has a thickness greater than the drift region.

### FIELD

The present invention relates to a silicon carbide lateral power semiconductor device.

### BACKGROUND

Wide bandgap power semiconductor devices are beginning to replace traditional silicon-based devices in a number of terrestrial applications including electric vehicles and solar inverters. This can help to deliver lighter, smaller, and more efficient power converter solutions across a number of applications, exploiting the ability of 600-1700 V silicon carbide (SiC) to operate at higher frequencies and temperatures that Si devices. The need to develop radiation hardened SiC power devices has been highlighted by both NASA and ESA for space applications including satellite power supplies, ionic thrusters and solar arrays. Reference is made to ESA “ESCC Radiation Test Methods and Guidelines”. However, to replicate the success of SiC power devices in space, they must be immune to the progressive build-up of charge, known as total ionizing dose (TID), and to single-event effects (SEEs) and single event burnout (SEB) caused by the interaction of high-energy particles, such as protons, neutrons and heavy ions.

Fundamentally, SiC has a number of positive material characteristics for surviving in high radiation conditions. This includes a high thermal conductivity and atomic displacement energy, while an average energy of 8-9 eV is required to create an electron-hole pair in SiC (around 3 times higher than Si). Commercially-available SiC MOSFETs have shown excellent TID immunity beyond ESA's ESCC standard, for example, as shown in A. Akturk et al., “Radiation Effects in Commercial 1200 V 24 A Silicon Carbide Power MOSFETs”, IEEE Transactions on Nuclear Science, volume 59, pages 3258-3264 (2012) (hereinafter referred to as “Akturk”). However, under heavy ion bombardment, commercially-available SiC devices have poor SEB and SEGR resilience at energies far below ESA's ESCC requirement, namely a fluence of 1×10⁷ particles/cm² at a linear energy transfer (LET) of 60 MeV·cm²/mg, as shown in A. F. Witulski et al., “Single-Event Burnout Mechanisms in SiC Power MOSFETs” IEEE Transactions on Nuclear Science, volume 65, number 8, pages 1951-1955 (2018) (hereinafter referred to as “Witulski”), E. Maset et al., “Prototyping and Characterization of 1.2 KV SIC Schottky Diodes for TWTA Application: The Challenge to Meet the User Specification” in E3S Web of Conferences, volume 16, page 12005 (2017) (hereinafter referred to as “Maset”), Akturk and also C. Abbate et al., “Gate Damages Induced in SiC Power MOSFETs During Heavy-Ion Irradiation—Part II,” IEEE Transactions on Electron Devices, volume 66, number 10, pages 4243-4250 (2019) (hereinafter referred to as “Abbate”).

Several groups have shown that current SiC devices, including Schottky diodes and MOSFETs, suffer severe, permanent, leakage current degradation at any LET above 10 MeV·cm²/mg, even at reduced off-state voltages, for example, at 200-500 V for a 1.2 kV power MOSFET, likely due to damage from self-heating, as shown in Witulski, Maset and Akturk. At higher voltages, catastrophic breakdown occurs. With only vertical unipolar devices available on the market and an absence of radiation-hard SiC products, their use requires significant derating.

### SUMMARY

According to a first aspect of the present invention there is provided a lateral silicon carbide power semiconductor device. The semiconductor device comprises a substrate, and a silicon carbide semiconductor structure disposed on the substrate and having a principal surface. The semiconductor structure comprises a layer of first conductivity type disposed on the substrate, and a layer-shaped drift region of a second conductivity type, which is opposite to the first conductivity type, disposed directly on the layer so as to form an interface between the layer and the drift region. The drift region runs laterally along the principal surface between first and second ends. Doping in the drift region and the layer are arranged so as to deplete the drift region (in other words, the region and layer have a RESURF configuration). The semiconductor device comprises a first contact region to the first end of the drift region. The semiconductor device comprises a second contact region to the second end of the drift region which is highly doped, which is of the first or second conductivity type, which may extend into the semiconductor structure from the principal surface, and which adjoins the second end of the drift region, is disposed in the drift region or is disposed in a region adjoins the second end of the drift region. The semiconductor device comprises a highly-doped region of the first conductivity type extending into the semiconductor structure from the principal surface and adjoining the first end of the drift region, wherein the highly-doped region has a thickness greater than the drift region.

This can provide a radiation hardened device. In particular, the RESURF structure enables a lateral configuration to be employed which can help reduce the statistical likelihood of a catastrophic ion impact, while the highly-doped region can provide an escape route for charged-carriers of the first conductivity type (e.g., holes) when recovering from a single-event fault and can also act to charge compensate the drift region: the deeper the highly-doped region, then the drift region can be doped to a higher concentration, which can reduce the device resistance.

The layer-shaped drift region may comprise at least first and second zones between the first and second ends of the drift region, wherein the doping concentration in the first region is lower than the doping concentration in the second region. Splitting the drift region into two or more regions can help to improve the electric field distribution in the drift region and can help the leakage current to recover or to recover more quickly after ion strike.

The layer-shaped drift region may have a doping profile such that the doping concentration increases between the first and second ends of the drift region.

The drift region may have a thickness of between 0.1 and 10 μm, between 0.1 and 2 μm, or between 0.2 and 0.8 μm. The drift region preferably has a thickness of between 0.45 μm and 0.55 μm, for example, 0.5 μm. The drift region may have a length between the first and second ends of between 2 and 35 μm or between 5 and 20 μm. The drift region may have doping concentration(s) between 5×10¹⁵ cm⁻³ and 1×10¹⁸ cm⁻³ or between 1×10¹⁶ cm⁻³ and 5×10¹⁷ cm⁻³. A first doping concentration in a first part (or “first zone”) of the drift region proximate the first end of the drift region is preferably lower than a second doping concentration in a second part (or “second zone”) proximate the second end.

The highly-doped region may extend a distance Δ below the interface between the layer and the drift region of between 0.1 and 10 μm, between 1 and 6 μm or between 2.5 and 5 μm. The highly-doped region may have a doping concentration of at least 1×10¹⁸ cm⁻³.

The first conductivity type may be p-type and the second conductivity type may be n-type.

The semiconductor device may comprise a dielectric layer disposed directly on the drift region having first and second ends, the dielectric layer partially covering the drift region. The dielectric layer may comprise a first contact window for contacting the first contact region. The dielectric layer may comprise a second contact window for contacting the second contact region.

The first contact region may comprise a portion of the drift region. The portion may be an end portion of the drift region proximate to the first end. The first contact region may be more highly doped than the drift region and which is of the first or second conductivity type. The first contact region may extend into the semiconductor structure from the principal surface. The first contact region may adjoin the first end of the drift region or be disposed in the drift region.

The semiconductor device may comprise a first terminal or first metallization layer arranged to contact the first contact region.

The semiconductor device may further comprise a shallow doped region of a first conductivity type at the end of the dielectric layer at the principal surface, preferably adjacent to an anode region or Schottky contact. The shallow doped region 140 can help to suppress off-state leakage. The shallow doped region may be p-type. The shallow doped region may be arranged as a ring. The shallow doped region may have a doping concentration of between 5×10¹⁷ cm⁻³ and 1×10¹⁹ cm⁻³, preferably about 1×10¹⁸ cm⁻³. The shallow doped region may have a thickness of between 10% and 50% of the thickness of the drift region, preferably between 15% and 25% of the thickness of the drift region. The shallow doped region may have a thickness of between 50 nm and 250 nm and may have a thickness about 100 nm. The shallow doped region may have a width of up to half the width w_{n-drift} of the drift region and may have a width between 100 nm and 5 μm.

The semiconductor device may further comprises a further doped region of a second conductivity type underlying and in direct contact with the doped region. This can be used to form a double RESURF structure. The further doped region may be n-type. The further doped region may be arranged as a ring. The further doped region may have a doping concentration of between 1×10¹⁷ cm⁻³ and 1×10¹⁹ cm⁻³. The further doped region may have a thickness of between 10% and 50% of the thickness of the drift region, preferably between 15% and 25% of the thickness of the drift region. The doped region may have a thickness of at least 50 nm and may extend to the upper surface of the layer of first conductivity type. The further doped region may be coterminous with the shallow doped region.

The semiconductor device may comprise a second terminal or second metallization layer arranged to contact the second contact region.

The drift region may extend into the structure from the principal surface, and the drift region may have a thickness between the interface and the principal surface. In the case of a single RESURF configuration in which the top of the drift region is the principal surface, the drift region may be depleted between the interface and the principal surface.

The lateral silicon carbide power semiconductor device may further comprise a layer-shaped region of a first conductivity type disposed directly on the drift region. Thus, a double RESURF structure may be used.

The lateral silicon carbide power semiconductor device may be configured to have a breakdown voltage of between 400 and 1000 V. Doping in the drift region may be constant between the first and second ends (in other words, be a single zone drift region). The lateral silicon carbide power semiconductor device may have a breakdown voltage of between 1000 and 1400 V. The lateral silicon carbide power semiconductor device may have a breakdown voltage of between 1400 and 3500 or between 1400 and 4000 V. The layer-shaped drift region may comprise at least first and second zones between the first and second ends of the drift region, wherein the doping concentration in the first region is lower than the doping concentration in the second region or the layer-shaped drift region has a doping profile such that the doping concentration increases between the first and second ends of the drift region.

The lateral silicon carbide power semiconductor device may be configured to be a Schottky barrier diode or a PiN diode. The first contact region may be the anode and the second contact region may be a cathode.

The lateral silicon carbide power semiconductor device may be configured to be a MOSFET. The first contact region may be the source and the second contact region may be a drain.

The lateral silicon carbide power semiconductor device may be configured to be an IGBT. The first contact may be an emitter and the second contact may be a collector.

The lateral silicon carbide power semiconductor device may comprise a gate and gate dielectric, wherein the gate dielectric is disposed directly on a portion of the drift region and is interposed between the gate and the drift region.

According to a second aspect of the present invention there is provided a monolithic semiconductor device comprising a plurality of the lateral silicon carbide power semiconductor devices of the first aspect.

According to a third aspect of the present invention there is provided a vehicle comprising the lateral silicon carbide power semiconductor device of the first aspect. The vehicle may be a (space) launch vehicle, a spacecraft, such as a satellite, an aircraft or other vehicle which may travel in an environment which is subject to ionizing radiation, heavy-ion irradiation and/or proton irradiation, for example, up to a fluence of 1×10⁷ particles/cm² at a linear energy transfer (LET) of 10 MeV·cm²/mg or 60 MeV·cm²/mg, such as an altitude above 7500 m, low-Earth orbit or beyond low-Earth orbit, beyond Earth orbit or the atmosphere of another planet, such as Mars.

According to a fourth aspect of the present invention there is provided instrumentation comprising the lateral silicon carbide power semiconductor device of the first aspect. The instrumentation may be for deployment in an environment subject to ionizing radiation, heavy-ion irradiation and/or proton irradiation, for example, up to a fluence of 1×10⁷ particles/cm² at a linear energy transfer (LET) of 10 MeV·cm²/mg or 60 MeV·cm²/mg. The environment may be proximate a cyclotron, proximate a reactor, an altitude above 7500 m, low-Earth orbit or beyond low-Earth orbit, beyond Earth orbit or the atmosphere of another planet, such as Mars.

According to a third aspect of the present invention there is provided a method of operating the lateral silicon carbide power semiconductor device of the first aspect, the method comprising causing placement of the lateral silicon carbide power semiconductor device in an environment subject to ionizing radiation, to heavy-ion irradiation and/or proton irradiation and applying a bias of at least 400 v, at least 650V, at least 1200V, at least 2000V, or at least 3000V across the drift region.

### BRIEF DESCRIPTION OF THE DRAWINGS

Certain embodiments of the present invention will now be described, by way of example, with reference to the accompanying drawings, in which:

FIG. 1 is a schematic cross section of a vertical SiC Schottky barrier diode device, and first, second, third and fourth paths taken by ions through the device during heavy ion bombardment;

FIG. 2A is a plot of simulated peak electric field as a function of linear energy transfer and reverse voltage reached after a heavy ion passes vertically through the device shown in FIG. 1 along the first path;

FIG. 2B is a plot of simulated maximum temperature as a function of linear energy transfer and reverse voltage reached after a heavy ion passes vertically through the device shown in FIG. 1 along the first path;

FIG. 3A is a plot of simulated peak electric field as a function of linear energy transfer and reverse voltage reached after a heavy ion passes vertically through the device shown in FIG. 1 along the third path;

FIG. 3B is a plot of simulated maximum temperature as a function of linear energy transfer and reverse voltage reached after a heavy ion passes vertically through the device shown in FIG. 1 along the third path;

FIG. 4 is a plot of simulated current against time plots for the device shown in FIG. 1 and for a SiC lateral RESURF Schottky barrier diode device shown in FIG. 7 during recovery from heavy ion strike for ion strikes along first, third and fifth paths for a reverse voltage of 800 V and a linear energy transfer of 60 MeV·cm²/mg;

FIG. 5A is a plot of electric field against distance along a central cutline of drift region at t=0 s, 0.1 ns, 0.12 ns and 0.135 ns after an ion strike along the first path shown in FIG. 1, for a reverse voltage of 800 V and a linear energy transfer of 60 MeV·cm²/mg;

FIG. 5B is a plot of electron density against distance along a central cutline of drift region at t=0 s, 0.1 ns, 0.12 ns and 0.135 ns after an ion strike along the first path shown in FIG. 1, for a reverse voltage of 800 V and a linear energy transfer of 60 MeV·cm²/mg;

FIG. 5C is a plot of hole density against distance along a central cutline of drift region at t=0 s, 0.1 ns, 0.12 ns and 0.135 ns after an ion strike along the first path shown in FIG. 1, for a reverse voltage of 800 V and a linear energy transfer of 60 MeV·cm²/mg;

FIG. 5D is a plot of electric field against distance along a central cutline of drift region at t=0.3 ns, 0.7 ns, 1.5 ns and 2 ns after an ion strike along the first path shown in FIG. 1, for a reverse voltage of 800 V and a linear energy transfer of 60 MeV·cm²/mg;

FIG. 5E is a plot of electron density against distance along a central cutline of drift region at t=0.3 ns, 0.7 ns, 1.5 ns and 2 ns after an ion strike along the first path shown in FIG. 1, for a reverse voltage of 800 V and a linear energy transfer of 60 MeV·cm²/mg;

FIG. 5F is a plot of hole density against distance along a central cutline of drift region at t=0.3 ns, 0.7 ns, 1.5 ns and 2 ns after an ion strike along the first path shown in FIG. 1, for a reverse voltage of 800 V and a linear energy transfer of 60 MeV·cm²/mg;

FIG. 6A is a plot of electric field against distance along a central cutline of drift region at t=0 s, 0.1 ns, 0.12 ns and 0.135 ns after an ion strike along the third path shown in FIG. 1, for a reverse voltage of 800 V and a linear energy transfer of 60 MeV·cm²/mg;

FIG. 6B is a plot of electron density against distance along a central cutline of drift region at t=0 s, 0.1 ns, 0.12 ns and 0.135 ns after an ion strike along the third path shown in FIG. 1, for a reverse voltage of 800 V and a linear energy transfer of 60 MeV·cm²/mg;

FIG. 6C is a plot of hole density against distance along a central cutline of drift region at t=0 s, 0.1 ns, 0.12 ns and 0.135 ns after an ion strike along the third path shown in FIG. 1, for a reverse voltage of 800 V and a linear energy transfer of 60 MeV·cm²/mg;

FIG. 6D is a plot of electric field against distance along a central cutline of drift region at t=0.3 ns, 0.7 ns, 1.5 ns and 2 ns after an ion strike along the third path shown in FIG. 1, for a reverse voltage of 800 V and a linear energy transfer of 60 MeV·cm²/mg;

FIG. 6E is a plot of electron density against distance along a central cutline of drift region at t=0.3 ns, 0.7 ns, 1.5 ns and 2 ns after an ion strike along the third path shown in FIG. 1, for a reverse voltage of 800 V and a linear energy transfer of 60 MeV·cm²/mg;

FIG. 6F is a plot of hole density against distance along a central cutline of drift region at t=0.3 ns, 0.7 ns, 1.5 ns and 2 ns after an ion strike along the third path shown in FIG. 1, for a reverse voltage of 800 V and a linear energy transfer of 60 MeV·cm²/mg;

FIG. 7 is a schematic cross section of a simplified SiC lateral RESURF Schottky barrier diode device, and a fifth path taken by an ion through the device during heavy ion bombardment;

FIG. 8A is a plot of simulated peak electric field as a function of linear energy transfer and reverse voltage reached after a heavy ion passes vertically through the device shown in FIG. 7 along the fifth path;

FIG. 8B is a plot of simulated maximum temperature as a function of linear energy transfer and reverse voltage reached after a heavy ion passes vertically through the device shown in FIG. 7 along the fifth path;

FIG. 9 is an orthogonal view of a two-zone RESURF Schottky barrier diode device, and a sixth path taken by an ion through the device during heavy ion bombardment;

FIG. 10 shows lateral surface electric field profiles of single-zone and two-zone RESURF Schottky barrier diodes device along a cutline at 50 nm below an interface between a field oxide and N− drift region;

FIG. 11A is a plot of current against forward voltage for single-zone and two-zone RESURF Schottky barrier diodes device;

FIG. 11B is a plot of current against reverse voltage for single-zone and two-zone RESURF Schottky barrier diodes device;

FIG. 11C is a plot of leakage current against time following a heavy ion strike showing SEB in a single-Zone RESURF Schottky barrier diodes device and recovery in a two-zone Schottky barrier diodes device for V_{R}=1200 V and LET=60 MeV·cm²/mg;

FIG. 12 is a plot of electric field against distance along a cutline 50 nm below the SiC surface in the N− drift region at t=0 s, 0.1 ns, 0.15 ns, 0.25 ns, 0.5 ns, 0.7 ns and 1 ns in a single-zone RESURF Schottky barrier diode device as it burns-out following a 60 MeV·cm²/mg heavy ion passing through it while supporting 1200V;

FIG. 13 is a plot of electric field against distance along a cutline 50 nm below the SiC surface in the N− drift region at t=0 s, 0.1 ns, 0.15 ns, 0.25 ns, 0.5 ns, 0.7 ns and 1 ns in a two-zone RESURF Schottky barrier diode device as it burns-out following a 60 MeV·cm²/mg heavy ion passing through it while supporting 1200V;

FIG. 14 is a plot of breakdown voltage against first zone doping concentration in a RESURF Schottky barrier diode device for pillar depths of 1 μm, 1.5 μm, 2.5 μm, 3 μm and 5 μm;

FIG. 15 is a cross-sectional view of a radiation-hard Schottky barrier diode device;

FIG. 16 is a plan view of the Schottky barrier diode device shown in FIG. 16;

FIG. 17 is a plan view of a modified Schottky barrier diode device having intercalated highly-doped region;

FIG. 18 is a cross-sectional view of a radiation-hard PiN diode;

FIG. 19 is a cross-sectional view of a radiation-hard MOSFET;

FIG. 20 is a cross-sectional view of a radiation-hard IGBT;

FIG. 21A shows a doping profile in a single-zone drift region;

FIG. 21B shows a doping profile in a two-zone drift region;

FIG. 21C shows a doping profile in a graded drift zone;

FIG. 22 is a process flow diagram of a method fabricating a radiation-hard device;

FIG. 23 illustrates a layer structure for use in a double-RESURF layer structure;

FIG. 24 illustrates a first structure for helping to suppress off-state leakage;

FIGS. 25A to 25I illustrate alternative structures for helping to suppress off-state leakage.

### DETAILED DESCRIPTION OF CERTAIN EMBODIMENTS

### Introduction

Herein, SiC power device geometries are disclosed which can help achieve a radiation hardened layout able to achieve the required SEE conditions. Single event simulations are performed in TCAD on 1200V-rated vertical SiC Schottky Barrier Diode (SBD) structures to expose the weakness of this layout. The relative strength of laterally designed SiC devices is then explored by first passing ions laterally across the same SBD, before considering an optimized reduced-surface-field (RESURF) topology to further exploit this.

### Simulation Methodology

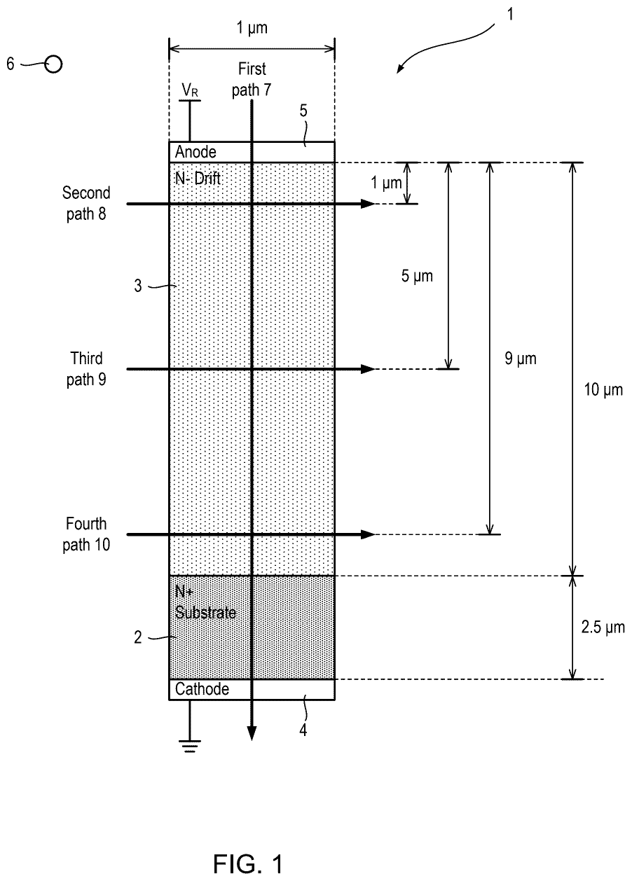

Referring to FIG. 1, a simplified 1200 V rated vertical SBD 1 is shown.

The SBD 1 comprises a N+ substrate 2 having a thickness of 2.5 μm and a N− drift region 3 disposed on the substrate 2 having a thickness of 10 μm, and a cathode 4 and an anode 5 connected to the substrate 2 and drift region, respectively. The device 1 has a width of 1 μm.

The SBD 1 is simulated in Synopsys® Sentaurus TCAD to investigate SEEs caused by a heavy ion 6. Four ion paths 7, 8, 9, 10 across the drift region are considered in order to investigate the influence of the impact position on the device response. Given the layout of a vertical device, that has a thin drift region (10 μm in this case), and a device area of the order of millimetres squared, heavy ions will typically traverse both terminals of the device. This is represented by the first path 7. The simulation, however, can also use this same model to see what would occur in an idealized lateral device. Accordingly, second third and fourth paths 8, 9, 10 corresponding to the top, middle and bottom of the device are considered.

The model parameters are listed in Table I below. In each position (i.e., for each path), a 2D matrix of results is derived from using a heavy ion simulated with a linear energy transfer (LET) varying from 10 to 60 MeV·cm²/mg, crossing the SBD 1 with a reverse voltage V_{R} from 100 to 1200 V. In a dynamic simulation, a heavy ion strike occurs 0.1 ns after the simulation starts to give the device simulation sufficient time to achieve the steady state. For each simulation, the peak electric field in the drift region 3, and the maximum temperature are recorded and plotted.

TABLE I
PARAMETERS USED IN TCAD SIMULATIONS

| Parameter | Value | |
|---|---|---|
| 4H-SiC | Bandgap = 3.26 eV | |
| Schottky metal work function | 5.1 | eV |
| N− epi doping/depth | 1 × 10¹⁵ cm⁻³, 10 μm | |
| N+ substrate doping/depth | 1 × 10¹⁹ cm⁻³, 2.5 μm | |
| Initial temperature | 300 | K |

| | |
|---|---|
| Ion Track Radius/Length | 50 nm, 12.5 μm |
| Impact Ionization Model | Anisotropic Avalanche |

### Results and Discussion

### Peak Electric Field and Maximum Temperature

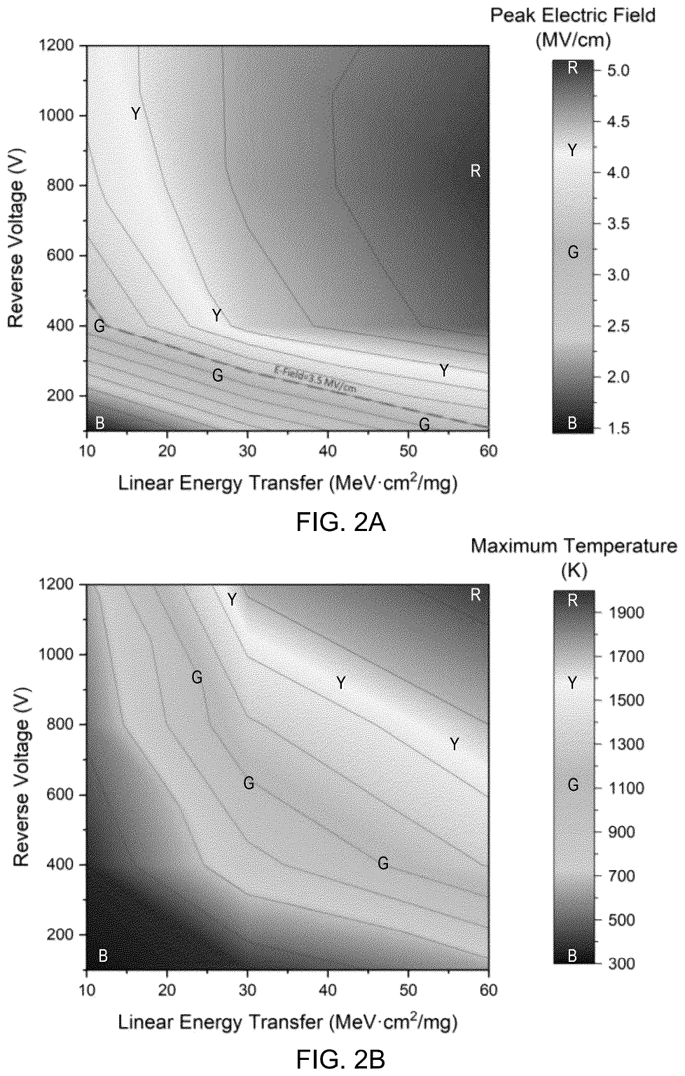

Referring to FIGS. 2A and 2B, peak electric field and temperature simulation results are shown for the case in which a heavy ion passes through the device vertically, namely along the first path 7, in which the ion path is in the same direction as the electric field vector.

The peak electric field and temperature simulation results agree well with previously reported experimental and simulation results on SEE in SBDs, such as Akturk and Abbate. It can be seen that at low LET, and/or low voltage, the rise in temperature can be limited to a localized peak value less than 700 K.

Referring in particular to FIG. 2A, the dotted line denotes the boundary above which the peak electric field exceeds 3.5 MV/cm. This result can be seen to resemble the threshold presented in Witulski between the experimentally-tested JBS diodes that demonstrated no observable damage at low values of reverse voltage and those that suffered damage and a permanent increased leakage current, from approximately 200-500 V. In this voltage range, temperatures are shown to exceed 1000 K where the ion strike occurred, at the semiconductor surface, beneath the Schottky contact. This explains the lasting increase in leakage: heating is equivalent to a localized rapid thermal anneal of the contact, giving over to areas of Schottky barrier inhomogeneity and, hence, leakage. Beyond this, the simulations reach extreme peak temperatures of up to 2000 K and the electric field exceeding 5 MV/cm, resulting in catastrophic failure.

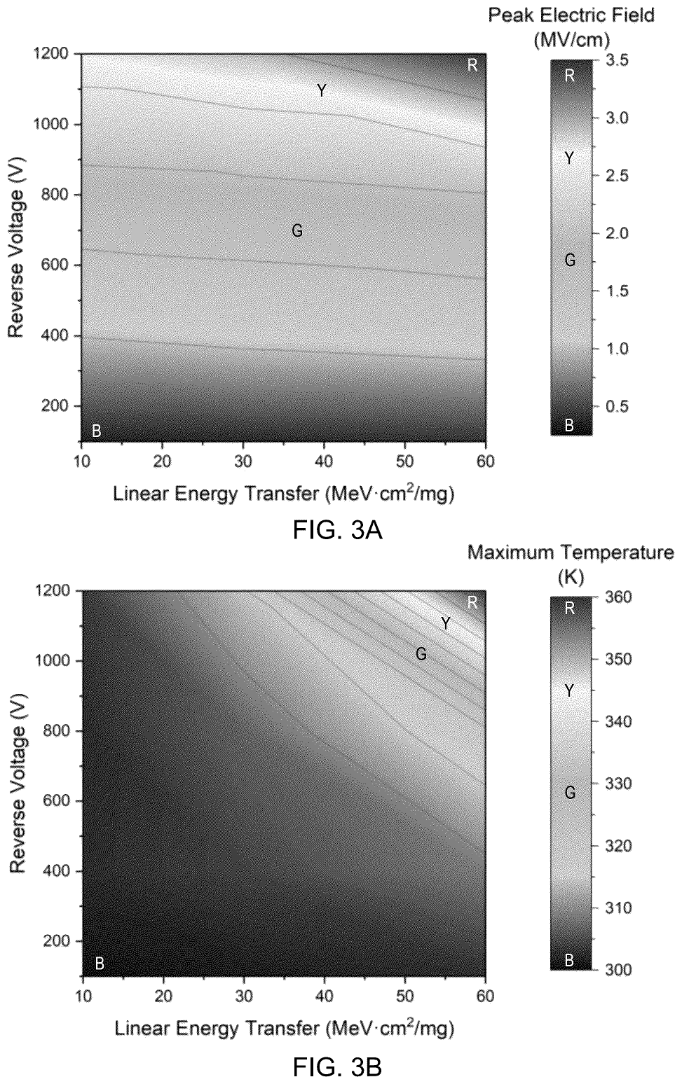

Referring to FIGS. 3A and 3B, by contrast, the simulations of the SBD undergoing horizontal ion strikes along the second, third and fourth paths 8, 9, 10 point to potential immunity in a lateral SiC device, in which the ion strike is perpendicular to the electric field vector. The three ion paths produce similar results, the worst being the third path, the simulation results of which are shown in FIGS. 3A and 3B. At 800 V and 60 MeV·cm²/mg, simulations for the second, third and fourth paths resulted in peak electric fields of 3.47, 3.50 and 3.53 MV/cm, respectively, and maximum temperatures of 353, 360 and 346 K, respectively.

### Dynamic Current and Electric Field Characteristics

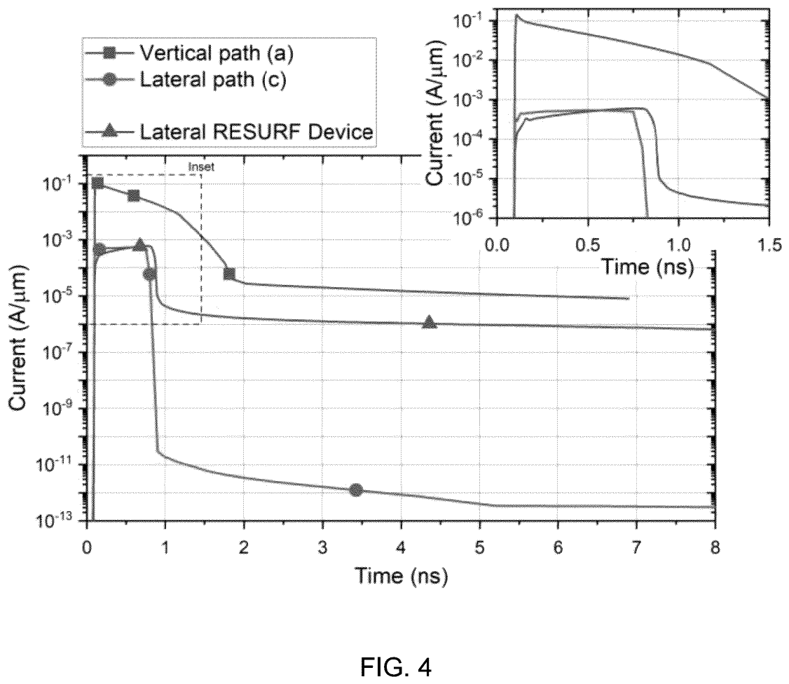

Referring to FIG. 4, dynamic progression of current for ion strikes along the first and third paths 7, 9 are shown.

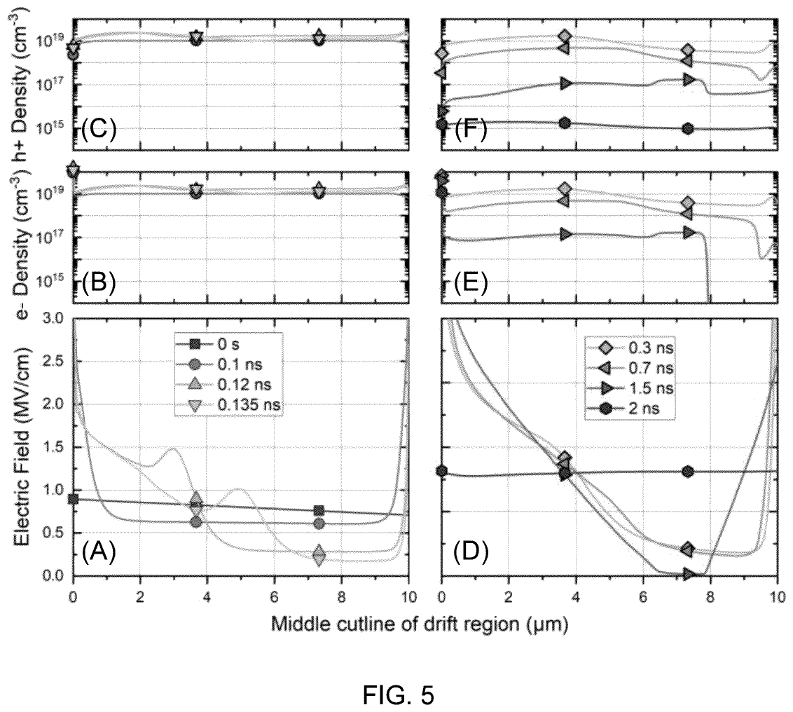

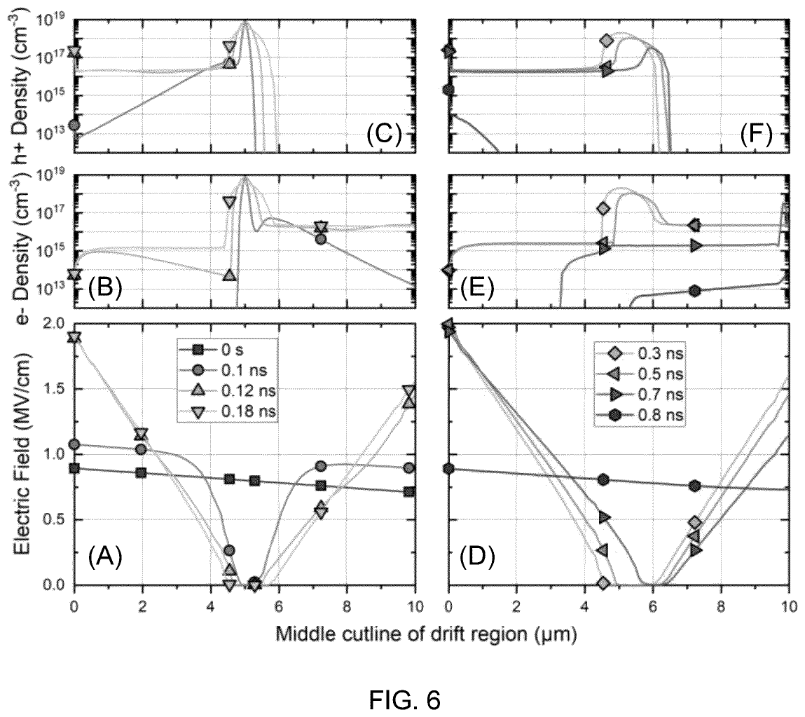

Referring to FIGS. 5A to 5F and 6A to 6F, dynamic electric field, electron density and hole density are shown which provide a more detailed understanding of these contrasting events.

The results are for cases in which the reference voltage is 800 V and LET is 60 MeV·cm²/mg. In all these cases, the steady-state leakage current for t<0.1 ns was extremely low and the electric field peaked at 0.89 V/cm. At t=0.1 ns, the heavy ion event creates a narrow filament of 10¹⁹ cm⁻³ electron-hole pairs along each ion path. This immediately causes a disruption to the previously uniform depletion region and the process of charge extraction brings about a current, while the device is still blocking the rated voltage, thus creating a large instantaneous power.

In the vertical case, the current filament results in a temporary short between the anode 5 (FIG. 1) and cathode 4 (FIG. 1) which allows a flow of current.

Referring in FIGS. 5A to 5F, a significant density of electrons and holes are present throughout the entire ion path vector, meaning there is little space to support the 800 V supply voltage. As such, two spikes of electric field occur at the edges of the drift region 3 (FIG. 1), the field exceeding 5.5 MV/cm at the interface between the metal and the N− drift region 3 (FIG. 1), and 3.9 MV/cm between the N− drift and N+ substrate regions 2, 3 (FIG. 1). Carrier sweep out is slow, hindered by the influx of external charge, but by 2 ns, a depletion region has formed from each end, and the remaining charge is concentrated in the middle. The final excess charge carriers recombine and the leakage current falls slowly towards its initial value.

Cases involving horizontal paths can have two advantages. First, a short does not occur between the terminals 4, 5 (FIG. 1), and any charge that is generated is located in a narrow region along the central cutline. This means there is sufficient space above and below the ion track to support the reverse voltage, and the electric field reaches just 2 MV/cm at the surface. Secondly, the current sweep out is more orderly whereby electrons are swept toward the cathode, and holes are swept to the anode. By 0.8 ns the electric field distribution returns to its steady state profile and the final excess charge carriers start to recombine.

The peak current and peak power are 284 times greater for the vertical path than for the horizontal device, while the total charge extracted (the area under the traces shown in FIG. 4) are 130 times larger for the vertical path. These values underline the impact of an ion passing between both terminals, causing a temporary short.

This initial study demonstrates the catastrophic impact of a vertical ion path through the SiC drift region 3 with its high electric field. Employing a lateral device topology can help make such a catastrophic impact much less likely.

### First, Simplified SiC RESURF Schottky Diode

The simulation results hereinbefore described suggest that a lateral topology is a potentially favourable for radiation-hardening SiC power devices. A lateral topology offers not only the geometrical advantages of where the ion strikes, but also the option to produce highly efficient, charge compensated structures. In particular, a reduced-surface-field (RESURF) layout allows a p-layer to be added beneath the drift region, which aids the extraction of holes generated during a single event.

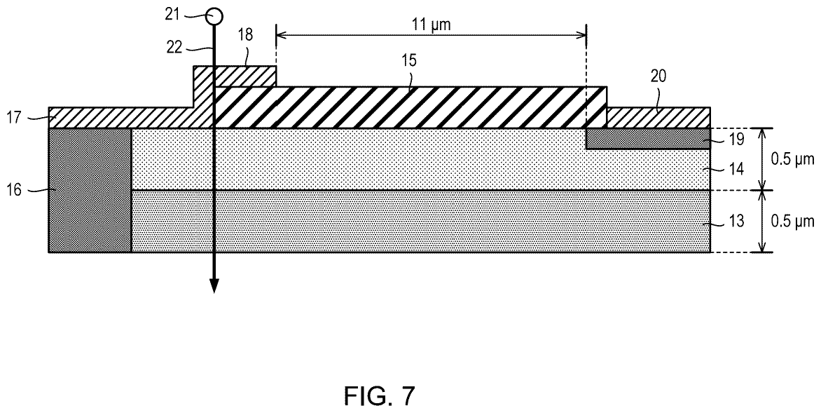

Referring to FIG. 7, a first, simplified 1200 V rated lateral RESURF SBD 11 is shown.

The first lateral RESURF SBD 11 comprises a substrate (not shown) comprise a P− layer 13 having a thickness of 0.5 μm, a N− drift region 14 having a thickness of 0.5 μm is disposed on the P− layer 13 and a field oxide 15 disposed on the N− drift region 14. A P+ pillar 16 is formed adjacent to the P− and N− layer 13, 14. An anode 17 is formed over the top of the P+ pillar 16 and the end of the N− layer 14. The anode metallization extends over and onto the field oxide 15 to form a field plate 18. An N+ well 19 is formed in the N− drift region 14 at the at the other end of the field oxide 15. A cathode 20 is formed on the N+ well 19. The P− and N− layers 13, 14 both have a doping concentration of 1×10¹⁷ cm⁻³. The width of the drift region is 11 μm. The breakdown voltage (BV) may be maximized by optimizing the field plates and oxide thickness.

The first lateral RESURF SBD 11 is simulated using Synopsys® Sentaurus TCAD to investigate SEEs caused by a heavy ion 21. The path 22 of a vertical ion strike occurs perpendicular to the electric field vector and is at the edge of the Schottky contact, where the field is at its maximum in the off-state.

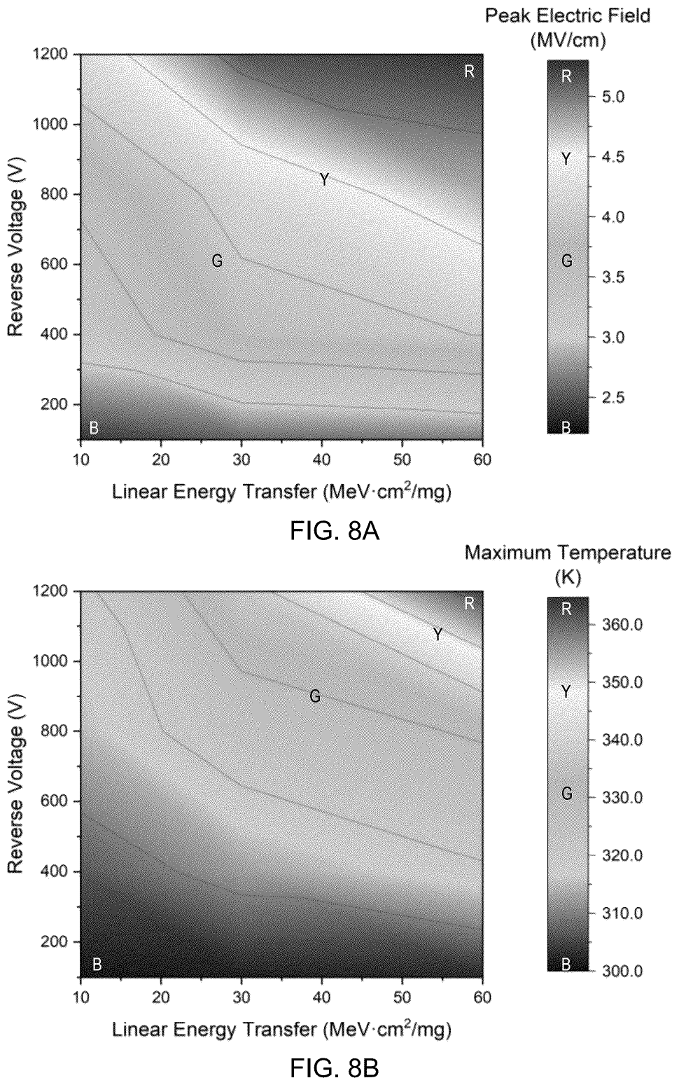

Referring to FIGS. 8A and 8B, peak electric field and temperature simulation results are shown for the case in which a heavy ion passes through the first lateral RESURF SBD 11 vertically, namely along the fifth path 22.

The simulation shows immunity of the first lateral RESURF SBD 11. The peak field reaches 5.29 MV/cm, while the temperature is limited to a rise of 64 K.

Referring also for FIG. 4, the current response after a 60 MeV·cm²/mg heavy ion strike at 800 V is compared to the vertical and lateral paths through the device 1 hereinbefore described. The response of the first lateral RESURF SBD 11 to the single event is almost identical to the previous lateral device 1 during the first 1 ns. The amount of charge extracted in total is only 4% higher.

Simulations of simplified lateral RESURF device 11 suggest that it could support 1800 V, with a low resistivity due to the high drift region doping. An improved device is therefore considered.

### Second SiC RESURF Schottky Device

Simulations of the devices hereinbefore described suggest that a lateral, RESURF-based device has the potential to succeed in high radiation applications.

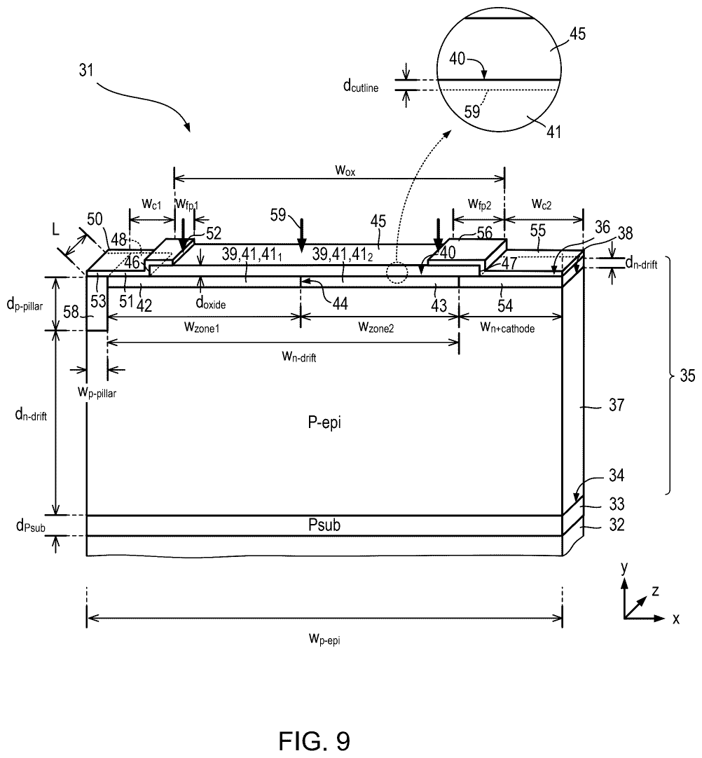

Referring to FIG. 9, a second lateral RESURF device 31 is shown.

The second lateral RESURF device 31 includes a heavily-doped n-type 4H-SiC substrate 32 (the substrate 32 is hereinafter referred to as an “N+ substrate”). An epitaxial layer 33 of heavily-doped p-type monocrystalline SiC is grown on the N+ substrate 32 which acts as field stop (the layer 33 is hereinafter referred to as the “P+ layer” or “Psub”). In this example, the P+ layer 33 has a depth (or “thickness”) d_{Psub} of 1 μm and a doping concentration of 1×10¹⁹ cm⁻³.

The P+ layer 33 has an upper surface 34 which supports a layer structure 35 having a principal surface 36 (or “upper surface”). The layer structure 35 includes an epitaxial layer 37 of lightly-doped p-type monocrystalline SiC (herein also referred to as the “P− epi layer”) having an upper surface 38 (herein also referred to as the “interface”) and a layer 39 of lightly-doped n-type monocrystalline SiC (herein also referred to as the “n-drift layer”) having an upper surface 40 and which provides a drift region 41. In this case, the P-epi layer 37 has a depth (or “thickness”) d_{P-epi} of 11 μm and the n-drift layer has a depth d_{n-drift} of 0.5 μm and a width w_{n-drift} of 17 μm between first and second ends 42, 43. To fully deplete the drift region 39 before breakdown, the P-epi layer 37 has a doping concentration NA, p-epi of 1×10¹⁵ cm⁻³.

There are two versions of the device 31. The first version of the device has a single-zone drift region 41 which has a doping concentration of N_{D,SZ,zone1}, N_{D,SZ,zone2} of 8.5×10¹⁶ cm⁻³. In the second version of the device, the drift region 41 is divided into first and second zones 41₁, 41₂ having a doping concentrations of N_{D,SZ,zone1} 6×10¹⁶ cm⁻³ and N_{D,SZ,zone2} of 1.5×10¹⁷ cm⁻³, respectively to improve the charge balance and optimise the breakdown voltage. The first and second zones 41₁, 41₂ are separated by a zone boundary 44.

A dielectric layer 45 in the form of a field oxide is disposed on the drift region 41. The dielectric layer 45 has thickness dₒₓ of 0.3 μm and a width wₒₓ of 16.5 μm between first and second ends 46, 47. The dielectric thickness dₒₓ may be between 200 nm and 3 μm. The dielectric layer 45 partially covers the drift region 41 and leaves a first contact window 48 at the first end 42 of the drift region 41.

A metallization contact layer 50 in the form of a layer of nickel runs over the first end 42 of the drift region 41 to provide a first contact 51 in the form of a Schottky barrier contact, and onto the dielectric layer 45 to form a field plate 52 for projecting junction corners. The metallization layer 50 also runs in the opposite direction to provide a contact 53 to a p− pillar 58.

A contact region 54 in the form of a heavily-doped n-type region is disposed in the layer structure 35, adjacent to the second end 43 of the drift region 41 at the principal surface 36. A metallization layer 55 in the form of a layer of nickel runs over the contact region 54 to provide a second contact 55 and onto the dielectric layer 45 to form a field plate 56.

A deep, highly-doped region 58 (herein also referring to as a “P+ pillar”) in the form of heavily-doped p-type region is disposed in the layer structure 35, adjacent to the first end 42 of the drift region 41 at the principal surface 36. As will be explained in more detail later, the P+ pillar 58 penetrates beyond the thickness of the drift layer 39, namely d_{P-pillar}=d_{n-drift}+Δ.

The n+ region 54 provides an escape path for electrons generated in the device after a single event while the device is off and reverse biased, while the P+ pillar 58 extracts holes generated by ion impact.

Table II below summarizes device dimensions and doping concentrations.

TABLE II
PARAMETERS OF RESURF SBD

| Symbol | Definition | Value | |
|---|---|---|---|
| w_{zone 1} | Zone 1 width | 9.35 | μm |
| w_{zone 2} | Zone 2 width | 7.65 | μm |
| d_{n-drift} | N-drift region depth | 0.5 | μm |
| Wₚ₋ₑₚᵢ/dₚ₋ₑₚᵢ | P-epi layer width and depth | 23 μm, 11 μm | |
| Wₚ₋ₚᵢₗₗₐᵣ/dₚ₋ₚᵢₗₗₐᵣ | P-pillar width and depth | 1 μm, 2.5 μm | |
| W_{n+cath}/d_{n+cath} | N+ cathode width and depth | 5 μm, 0.1 μm | |
| d_{oxide} | Oxide depth | 0.3 | μm |
| N_{D, SZ, zone1} | Zone 1 doping of Single-Zone | 8.5 × 10¹⁶ | cm⁻³ |
| N_{D, SZ, zone2} | Zone 2 doping of Single-Zone | 8.5 × 10¹⁶ | cm⁻³ |
| N_{D, 2Z, zone1} | Zone 1 doping of Two-Zone | 6 × 10¹⁶ | cm⁻³ |
| N_{D, 2Z, zone2} | Zone 2 doping of Two-Zone | 1.5 × 10¹⁷ | cm⁻³ |
| N_{A, p-epi} | P-epi layer doping | 1 × 10¹⁵ | cm⁻³ |
| N_{A, p-pillar} | P-pillar doping | 1 × 10¹⁹ | cm⁻³ |
| N_{D, n+cath} | N+ cathode doping | 1 × 10¹⁹ | cm⁻³ |

### On-State and Off-State Performance

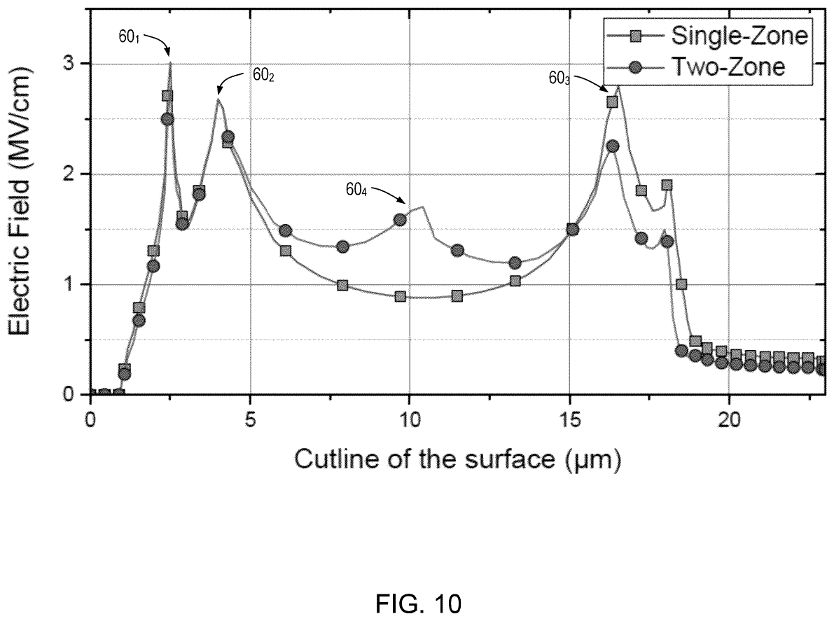

Referring to FIG. 10, lateral surface electric field profiles at breakdown for the single- and two-zone versions are shown. The electric field profiles are taken along a cutline 59 which is a distance d_{cutline}=50 nm below the interface 40 between the n-drift region 41 and the field oxide 45.

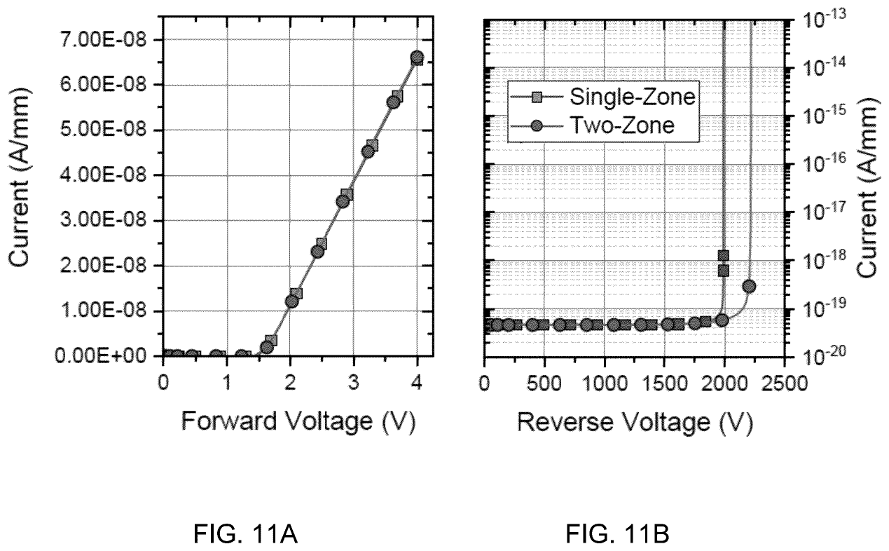

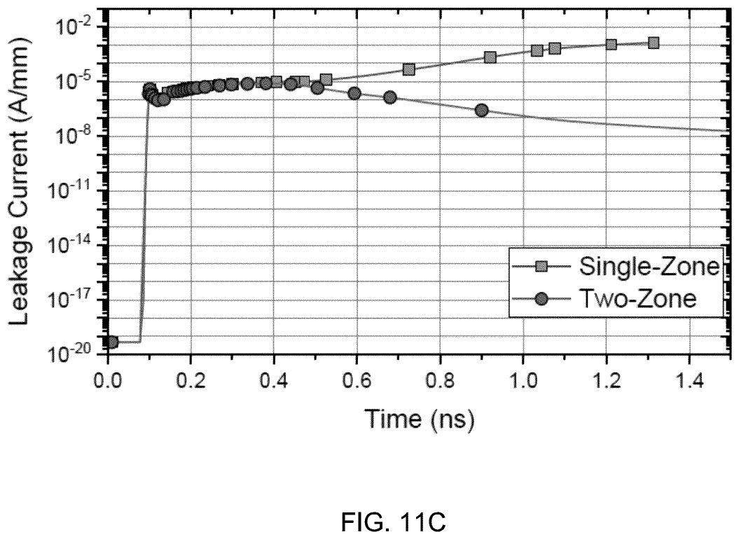

Referring also to FIGS. 11A, 11B and 11C, electrical characteristics of for the single- and two-zone versions are shown.

Referring in particular to FIG. 10, the single-zone device achieves ideal charge balance with a drift region doping concentration of 8.5×10¹⁶ cm⁻³. In this case, the slope of the electric field is uniform along the drift region 41 and the area under the electric field profile is maximized with three electric field peaks 601, 602, 603. The three peaks 601, 602, 603 are located in the drift region under each end of the anode field plate 52 and at the end of the cathode field plate 56 above the field oxide 44, with values of 3.01, 2.68 and 2.79 MV/cm respectively.

Referring in particular to FIG. 11B, the breakdown voltage of the single-zone Schottky barrier device is 1974 V.

Referring in particular again to FIG. 10, the two-zone device splits the drift region into a first, low doping zone 41₁ (“zone 1”) of 6×10¹⁶ cm⁻³, and a second, higher-doping zone 41₂ (“zone 2”) of 1.5×10¹⁷ cm⁻³. Compared to the single-zone drift region, the slope of the electric field in the first zone 41₁ is positive and the in the second zone 41₁ it is negative, resulting in one additional peak 604 at the interface 44 between the first and second zones 41₁, 41₂. As a result, the addition of the fourth electric field peak increases the area under the electric field profile, while simultaneously lowering the highest peaks.

Referring still to FIG. 10, from left to right, first, second, third and fourth peaks 601, 602, 603, 604 now reach 2.79, 2.67, 1.70 and 2.25 MV/cm.

Referring in particular to FIG. 11B, the resulting breakdown voltage of the two-zone RESURF SBD reaches 2061 V. The electric field distribution can still be improved by lower doping concentration in the first zone 1, but it also leads to worse on-state resistance.

The forward characteristics of the single- and two-zone RESURF SBDs can be seen in FIG. 11A.

Referring to FIG. 11A, the turn-on voltage of both the single- and two-zone RESURF SBDs are around 1.5 V, consistent with the work function of nickel of 5.1 eV. In the on-state, current passes through only the n-drift region 41 (FIG. 9), and the on-state resistance is therefore determined by its doping. Hence, the low doping of first, low doping zone 41₁ (FIG. 9) of the two-zone RESURF SBD results in its high on-state resistance, which at 3.63×10⁴ Ω·μm is 8% lower than the single-zone RESURF SBD, at 3.66×10⁴ Ω·μm. Overall, both the on-state and off-state performance are improved in this Two-Zone RESURF SBD.

Ideally, ever thinner n-drift regions could be used to further increase the doping, benefitting the on and off states, yet limitations in fabrication impose geometric limits.

### Single Event Effects

The single event immunity of both devices was tested via simulations carried out to ESA's standard, with the device off and supporting its rated voltage (V_{R}=1200 V) while undergoing a heavy ion LET of 60 MeV·cm²/mg. At 0.1 ns, the heavy ion is simulated to traverse the SBDs vertically (parallel to the y-axis) at the midpoint of the end of the cathode field plate 56 (FIG. 9). The arrow 59 shows the location and direction. Other entry positions were also simulated but the results were similar and hence are not presented. The dynamic progression of the current in each device is shown in FIG. 11C.

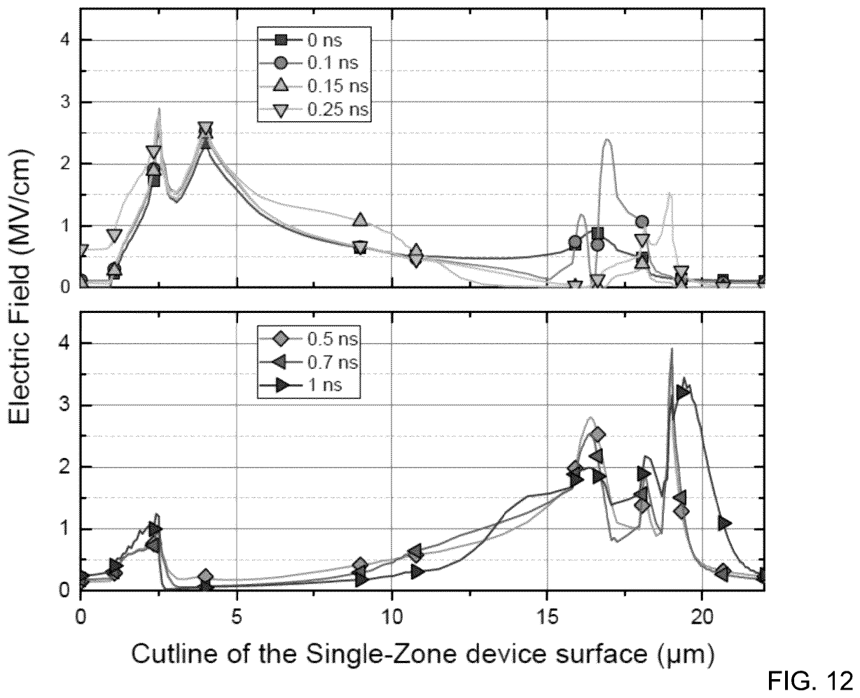

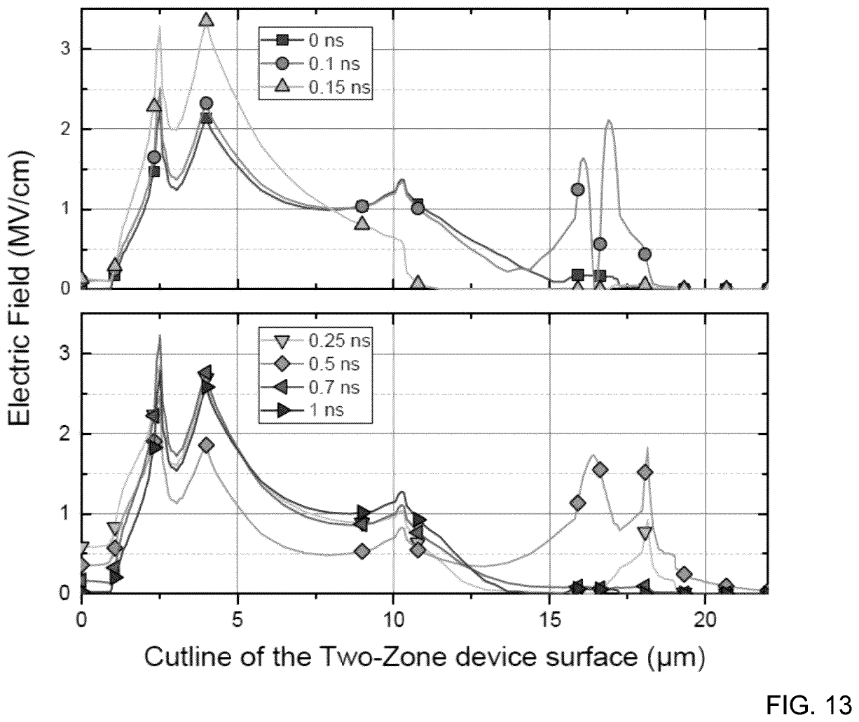

Referring to FIGS. 12 and 13, dynamic electric fields are shown. The electric field profiles are taken along the same cutline 59 which is 50 nm below the oxide-drift region interface 40.

Different responses to the heavy ion interaction occur, the single-zone device suffering burn-out due to a localised electric field spike, impact ionisation and eventually thermal runaway. The two-zone design recovers, the electric field staying below critical levels.

Without wishing to be bound by theory, the different outcomes for the two devices will now be explained.

Prior to the heavy ion event (t<0.1 ns), the single- and two-zone rectifiers were at room temperature and their steady-state leakage currents are extremely low (˜10²⁰ A/mm). At this time, with 1200 V applied, the two-zone device with its additional electric field spike has a maximum electric field of 2.27 MV/cm, 16% lower than the single-zone design.

At t=0.1 ns, a narrow filament of electron-hole pairs is immediately generated along each ion path by impact ionization. This breaks the uniform depletion region and suppresses the electric field where the ion crosses, as illustrated in FIGS. 12 and 13. In both cases, the process of charge extraction brings about a sharp rise in the current, seen in FIG. 11C.

In both devices, after 0.1 ns, the collapse in the electric field distribution in the centre of the drift region, is mirrored by an increase in the electric fields at the anode and cathode. Electrons and holes are swept out from the drift region, attracted to the n+ cathode 54 and the P+ implant 58 in that anode respectively by electric field.

In the single-zone SBD, at t=0.1 ns, the electric field at the edge of the anode contact 51 reaches 2.90 MV/cm. After that, this peak decreases the peak field shifting to the corner of the n+ cathode, where the electric field increases to 3.92 MV/cm at 0.7 ns.

At this point, this vast electric field is causing localised impact ionisation and hence the generation of many more carriers. The impact ionization coefficients for semiconductors are based on a modified form of Chynoweth's Law and is defined as:

$$α = a . {E}^{n} . {e}^{- ( b / E ) \hat{} m} \qquad ( 2 )$$

where E represents electric field, a and b are temperature-dependent parameters. From Equation 2, the presence of a high localized electric field leads to an increase of impact ionization rates. The generated carriers pile up around the cathode also making the electric field more severe. As a result, the current keeps growing in the single-zone device in FIG. 11C, a thermal runaway process occurs as the device gets hotter, more carriers get generated, the current gets larger, raising the temperature, and so on. SEB occurs in the single-zone RESURF SBD, by around 0.5 ns, as the current and temperature rise exponentially, leading eventually to burn out.

By contrast, in the two-zone SBD, the electric field spike of 3.35 MV/cm at t=0.15 ns, at the edge of the anode field plate, is the highest field experienced during its recovery. The carrier sweep-out raises the current, initially, in a manner identical to the single-zone design and hence the highest temperature in the device also occurs at the corner of the n+ cathode 54 (FIG. 9). Similar to the single zone device, after this point, this anode-side peak shrinks, and the cathode-side peak increases, to a maximum of 1.73 MV/cm at 0.5 ns. By this time, the current has peaked and with no impact ionisation and hence no more charge being generated, the current starts to reduce. By 1 ns the majority of charge has been extracted, and the electric field profile once more resembles the steady state value, the peak having shifted again, back to the anode side.

The differing outcomes of these two layouts and the field profiles seen in FIGS. 12 and 13 underline the importance of managing the cathode-side electric field spike.

Referring again to FIG. 10, if the two-zone device were modified to maximise only the device's breakdown voltage, then the doping of the second zone could be increased, such that the cathode-side electric field spike reached the critical field at the same voltage as the rest. However, it was more critical in this structure to achieve a balance in the electric field as the device was recovering from the single event at 1200 V. Given the dynamic field that moves from one end of the drift region to the other, the balance of an anode side 3.35 MV/cm spike at 0.15 ns, and a cathode-side 1.73 MV/cm spike at 0.5 ns could only be achieved by over doping in the second zone 41₂.

Referring again to FIG. 13, this explains the seemingly uneven 1200 V, two-Zone electric field profile, which can be seen at 0 ns to be skewed towards the anode side. This underlines the importance of a radiation-hard-by-design approach to developing these diodes.

### P− Pillar Depth

Referring again to FIG. 9, the P+ pillar 58 is formed under the anode-side Schottky contact 53 and is used to assist the extraction of holes generated during a single event.

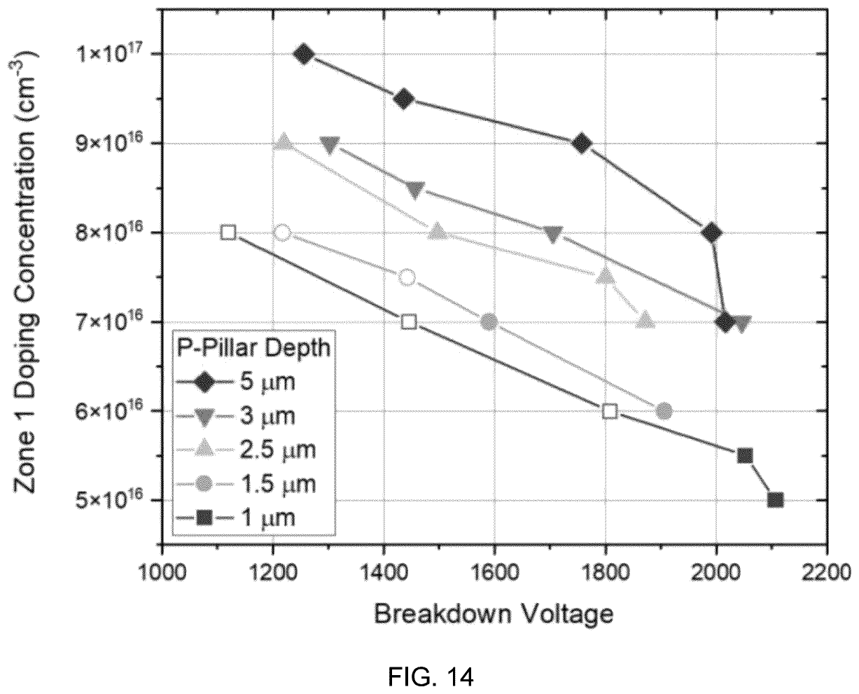

FIG. 14 illustrates the ability of a two-zone device to sustain single events for a range of doping concentration in the first zone 41₁ and for a fixed doping concentration of 1.5×10¹⁷ cm⁻³ in the second zone 41₂ for a range of pillar depths d_{P-pillar} (herein also referred to as “extensions”).

Referring to FIG. 14, filled symbols represent devices that can recover from a 60 MeV·cm²/mg heavy ion passing through the device while supporting 1200V, and the unfilled symbols represent devices that fail to recover following such an event.

In a device which has a first zone 41₁ having a doping concentration of 6×10¹⁶ cm⁻³ and pillar depth of 1 μm, although a breakdown voltage can be achieved 1808 V, the device fails to recover from a 60 MeV·cm²/mg heavy ion passing through it at 1200V. Reducing the doping to 5.5×10¹⁶ cm⁻³, the breakdown voltage increases to 2053 V, and the device successfully recovers from a 60 MeV·cm²/mg heavy ion passing through it at 1200V. 5.5×10¹⁶ cm⁻³ was the highest doping tested that was shown to successfully recover.

A device which as a first zone 41₁ having a pillar depth is 1.5 μm, a doping of 7×10¹⁶ cm⁻³ was the highest doping tested that was shown to successfully recover from a 60 MeV·cm²/mg heavy ion passing through it at 1200V. This device had a breakdown voltage of at 1590 V.

A device which as a first zone 41₁ having a pillar depth is 5 μm, a doping of 1×10¹⁷ cm⁻³ was the highest doping tested that was shown to successfully recover from a 60 MeV·cm²/mg heavy ion passing through it at 1200V. This device had a breakdown voltage of at 1255 V.

A deeper p− pillar extension leads to a higher first zone doping concentration in the RESURF SBD that is able to achieve the required SEE conditions. Therefore, the processing window for the first zone implantation becomes larger and the on-state performance is improved. This is because as the P+ pillar area becomes larger, as p-pillar depth is increased, the first zone doping concentration can be increased further to reach charge balance. Hence, the on-state resistance is reduced without sacrificing the blocking capability.

### Comments

Existing diodes suffer unacceptable off-state leakage degradation and catastrophic failure when subject to SEE tests at any appreciable voltage and LET. As shown herein, a vertical topology results in a shorting of the drift region and which tends to be catastrophic for a vertical device. A lateral device employing a RESURF layout, can help to provide significant single event immunity, preventing SEB, limiting both the electric field spikes, and the internal temperature rise.

Thus, rather than simply focusing on breakdown voltage, the lateral devices having a RESURF layout are configured to be a laterally charge balanced device in terms of its SEE recovery and be radiation hardened. A balanced recovery from 60 MeV·cm²/mg heavy ion event at 1200 V can be achieved by spatially varying the doping of the drift region, for example, by splitting it into two zones which can result in an extra electric field spike in the centre of the drift region. The device is arranged such that the doping concentration closer to the anode (for instance in the first of a two-zone drift region) is lower and the doping concentration closer to the anode is higher which can limit the electric field spike that occurs at the cathode end of the drift region. The presence of a deep p− pillar region at the anode side of the device further improves the device performance.

The approach herein described can be employed in different types of lateral power semiconductor devices including two-terminal devices, such as a Schottky barrier diode and PiN diode, and three-terminal devices, such as a metal-oxide semiconductor field effect transistor (MOSFET) and an insulated gate bipolar transistor (IGBT) as will now be described in more detail

### Schottky Barrier Diode

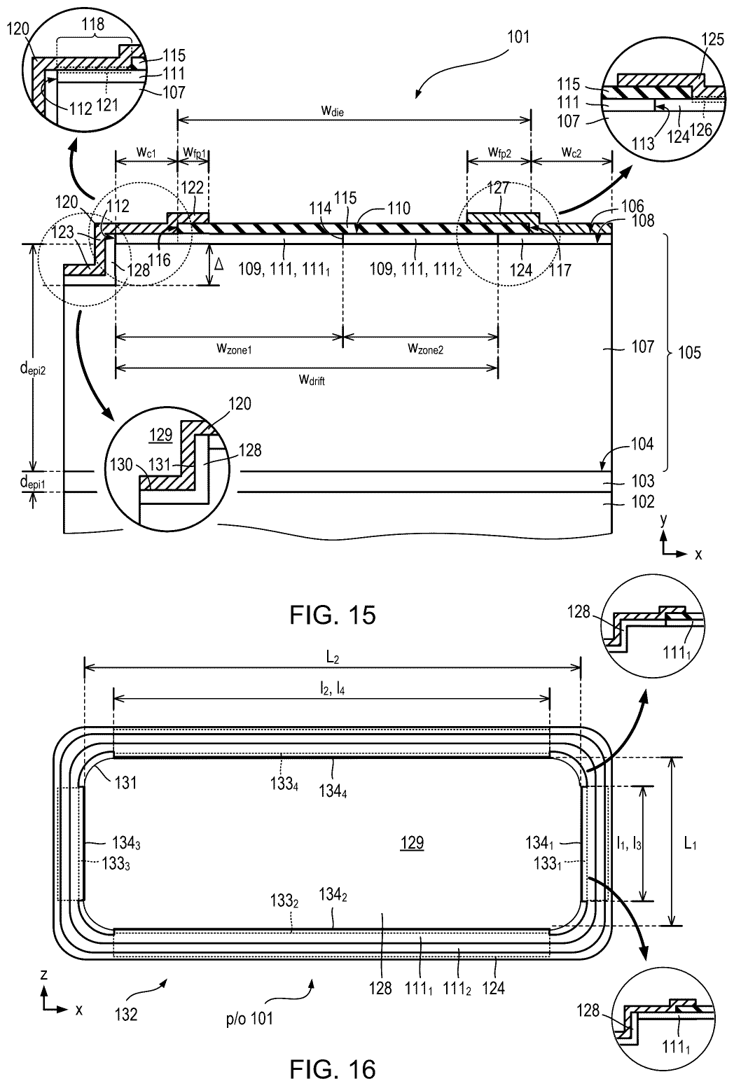

Referring to FIGS. 15 and 16, a lateral, RESURF-based SiC Schottky barrier diode 101 is shown. The Schottky barrier diode 101 is based on the second lateral RESURF device 31 (FIG. 9) hereinbefore described.

Referring in particular to FIG. 15, the Schottky barrier diode 101 is formed on a substrate 102 in the form of a heavily-doped, n-type, monocrystalline four-step hexagonal silicon carbide (4H—SiC). The substrate 102 may, however, be heavily-doped p-type 4H—SiC substrate, or be a substrate of a different material, such as silicon (Si), such as a silicon substrate or silicon-on-insulator (SOI) substrate.

The substrate 102 may support a first epitaxial layer 103 which is may be used to adapt a base substrate 102 which may have a given conductivity type (e.g., n-type), polytype, crystal orientation, defect density and/or material into a more suitable substrate. In this case, the semiconductor layer 103 takes the form a layer of heavily-doped p-type monocrystalline 4H—SiC and serves as a field stop. The first epitaxial layer 103 has a thickness dₑₚᵢ₁ of 1 μm and a doping concentration Nₑₚᵢ₁ of 1×10¹⁹ cm⁻³. The thickness dₑₚᵢ₁ and/or doping concentration Nₑₚᵢ₁ may, however, be lower or greater.

The first epitaxial layer 103 has an upper surface 104 which supports a layer structure 105 having a principal surface 106 (or “upper surface”).

The layer structure 105 includes a second epitaxial layer 107 which takes the form of lightly-doped SiC having a first conductivity type, in this case p-type, and having an upper surface 108 (herein also referred to as the “interface”) and a layer 109 of lightly-doped SiC (herein also referred to as the “drift layer”) having a second conductivity type opposite to the first conductivity type, in this case n-type, having an upper surface 110 and which provides a drift region 111. The second epitaxial layer 107 has a depth dₑₚᵢ₂ of 11 μm and a doping concentration Nₑₚᵢ₂ of 1×10¹⁵ cm⁻³. The drift layer 109 has a depth d_{drift} of 0.5 μm and a width w_{drift} of 17 μm between first and second ends 112, 113. To fully deplete the drift region 109 before breakdown, the second epitaxial layer 107 has a doping concentration Nₑₚᵢ₂ of 1×10¹⁵ cm⁻³.

The drift region 111 may be laterally divided between first and second ends 112, 113 into two or more zones 111₁, 111₂ having respective widths w_{zone1}, w_{zone2} and respective doping concentrations N_{zone1}, N_{zone2}, where N_{zone1}<N_{zone2}. In this example, the widths w_{zone1}, w_{zone2} are 11 μm and 7.5 μm respectively, and the doping concentrations N_{zone1}, N_{zone2} are 6×10¹⁶ cm⁻³ and 8.5×10¹⁶ cm⁻³, respectively. As will be explained in more detail later, the doping concentration in the drift region 111 may be graded. The zones 111₁, 111₂ are separated by a zone boundary 114.

A dielectric layer 115 in the form of a field oxide is disposed on the drift region 111. The dielectric layer 115 has thickness d_{die} of 0.3 μm and a width w_{die} of 20 μm between first and second ends 116, 117. The dielectric layer 115 may, however, be thinner or thicker, and/or comprise another suitable dielectric material. The dielectric layer 115 partially covers the drift region 111 and leaves a first contact window 118 having a width w_{c1} from the first end 112 of the drift region 111. The first contact window width w_{c1} is 3 μm.

A first metallization layer 120 in the form of a layer of nickel runs over the first end 112 of the drift region 111 to provide a first contact 121 in the form of a Schottky barrier contact, and onto the dielectric layer 115 to form a field plate 122 having a width w_{fp1} for projecting junction corners. The first field plate width w_{fp1} is 1.5 μm. The metallization layer 120 also runs in the opposite direction to provide a contact 123 to a p− pillar 128.

A contact region 124 in the form of a heavily-doped n-type region is disposed in the layer structure 105, adjacent to the second end 113 of the drift region 111 at the principal surface 106. The contact region 124 is formed by implanting a portion of a third epitaxial layer (not shown) which provides the drift layer 109.

A second metallization layer 125 in the form of a layer of nickel runs over the contact region 124 to provide a second contact 126 and onto the dielectric layer 115 to form a field plate 127.

A deep, highly-doped region 128 (herein also referring to as a “pillar”) in the form of heavily-doped p-type region is disposed in the layer structure 35, adjacent to the first end 112 of the drift region 111 at the principal surface 106.

The pillar 128 is formed using a trench 129 which passes through the drift layer 109 and into the second epitaxial layer 107. The trench has a depth d_{trench}, for example, of 2 μm. The trench 129 has a bottom 130 and a sidewall 131, and pillar 128 is formed by implanting dopants into the bottom 130 and sidewall 130, 131.

Referring also to FIG. 16, the Schottky barrier diode 101 is formed around the trench 129 in a rectangular self-terminating structure with an annular doping layout 132. In FIG. 16, the field oxide 115, and first and second metallization layers 120, 125 are omitted for clarity.

The device 101 has four active channels 133₁, 133₂, 133₃, 133₄ formed in the middle of each of edge 134₁, 134₂, 134₃, 134₄ of the trench sidewall 131. The trench 129 has sides L₁, L₂ of 180 and 480 μm. The corners may be curved. The active channels 134₁, 133₂, 134₃, 134₄ have length l₁, l₂, l₃, l₄ which are 100 μm, 400 μm, 100 μm and 400 μm respectively. Thus, the total length of active channel is 1000 μm.

The device 101 may be smaller, for example, with a trench 131 having sides L₁, L₂ of 130 and 280 μm to provide a total length of active channel of 500 μm. The device may be smaller or larger.

### Intercalated Highly-Doped Region

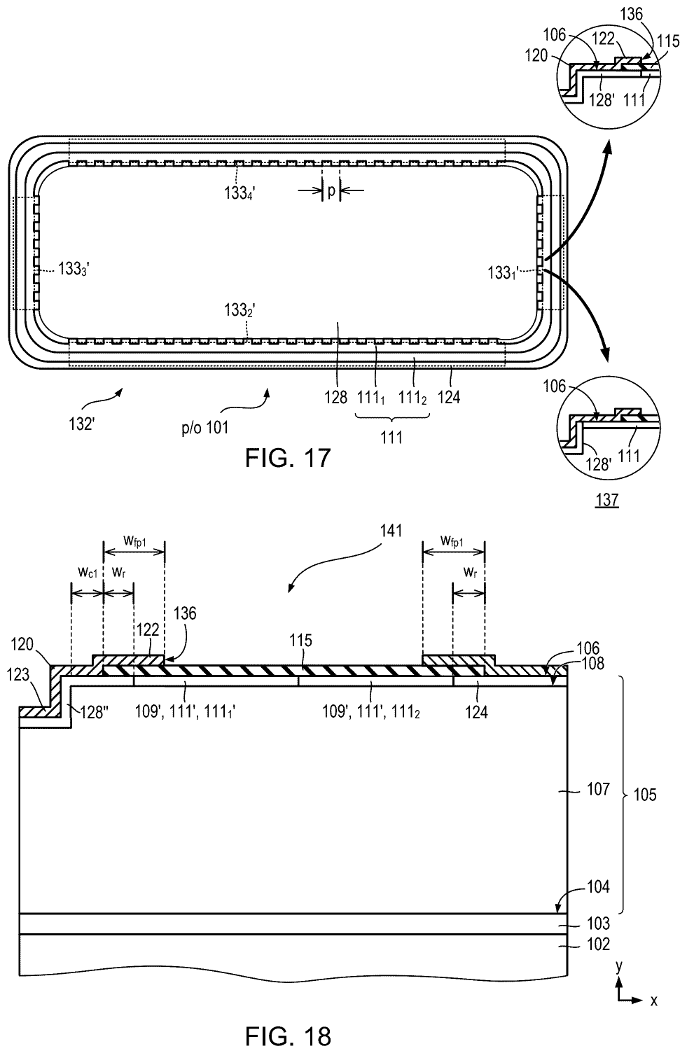

Referring to FIG. 17, a modified doping layout 132′ is shown.

The modified doping layout 132′ differs from the doping layout 132′ shown in FIG. 132 in that an intercalated highly-doped region 128′ having a castellated boundary is used.

Along the length of the channel 133₁′, 133₂′, 133₃′, 133₄′, the width of the highly-doped region 128′ which is used to provide the highly-doped pillar (e.g., p− pillar) periodically increases and decreases with a pitch p. In wide portions 135, the highly-doped region 128′ extends along the principal surface 108 under the dielectric layer 115 to the edge 136 of the first field plate 122. In narrow portions 137, the highly-doped region 128′ reaches the principal surface 108, but stops at the end of the drift region 111. The pitch p may be between 0 and 10 μm (i.e., 0<p≤10 μm), for example, 4 or 5 μm.

### PiN Diode

Referring to FIG. 18, a lateral, RESURF-based SiC PiN diode 141 is shown.

The PiN diode 141 is the same as the Schottky barrier diode 101 (FIG. 15) hereinbefore described, but differs in that the Schottky barrier contact is replaced by an ohmic contact to a region of highly-doped material of first conductivity type (in this case p-type) and the drift region is modified to accommodate the highly-doped p region. In this case, the highly-doped p-type material is provided by the implantation which is used to provide the p− pillar.

Along the length of the channel, a highly-doped p-type SiC region 128″ extends along the principal surface 108 under the dielectric layer 115 and under the first field plate 122 (but not to the edge 136) and a shorter drift region 111′ is used accordingly. Thus, the highly-doped p-type region 128′ provides a heavily-doped p-type region which forms a junction with the lightly-doped n-type region 111′ which in turn forms a junction with the heavily-doped n-type region 124 thereby providing a p-i-n diode structure.

In this case, the highly-doped p-type region 128″ extends under the first field plate 122 by an overlap distance wᵣ of 1.5 μm, the first contact window size war is 1.5 μm and the field plate size w_{fp1} is 1.5 μm. Other values of first contact window size We may be used, and the overlap distance wᵣ may be 0<wᵣ<w_{fp1}, preferably, 0.2w_{fp1}≤wᵣ≤0.8w_{fp1}.

### MOSFET

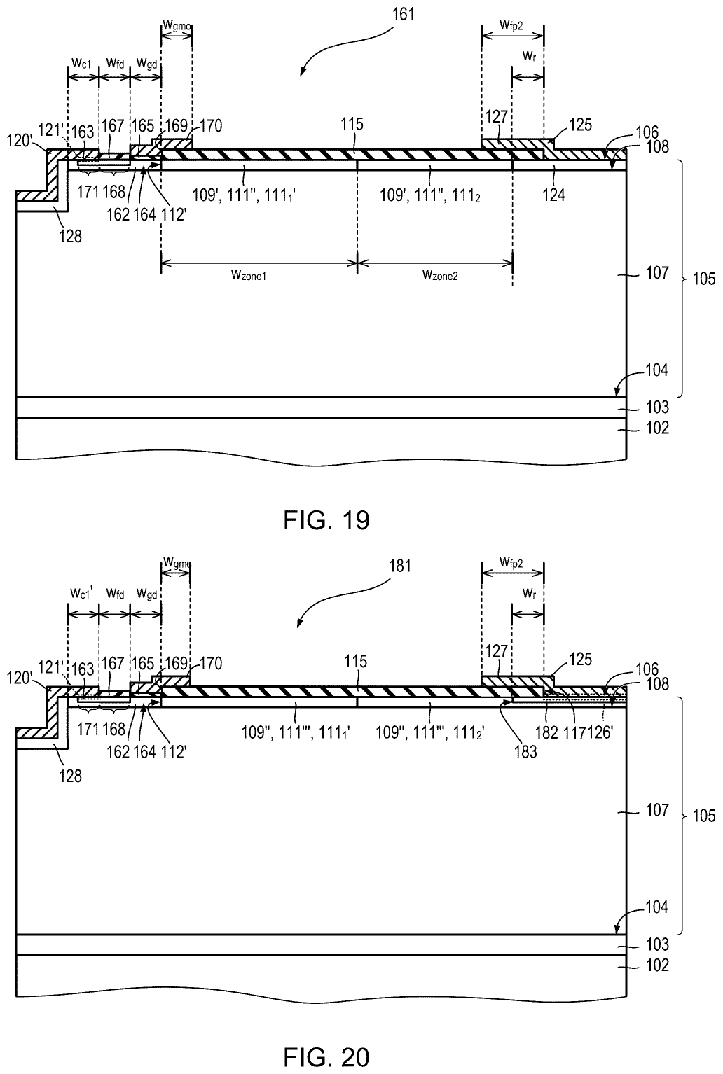

Referring to FIG. 19, a lateral, RESURF-based SiC MOSFET 161 is shown.

The MOSFET 161 is the same as the Schottky barrier diode 101 (FIG. 15) hereinbefore described, but differs that the Schottky barrier contact is replaced by an ohmic contact to a region of highly-doped material of second conductivity type (in this case n-type), the retrograde region of first conductivity type (in this case p-type) is introduced which provides a channel, and a gate-structure is provided over the channel.

A retrograde p-type region 162 is interposed between the highly-doped p-type region 128 and the n-type drift region 111″ at the principal surface 106. The retrograde p-type region 162 has a doping profile which increases in concentration from the principal surface 106 towards the substrate 102. The retrograde p-type region 162 has a thickness the same or similar to that of the n-type drift region 111″.

A highly-doped n-type well 163 is disposed within the retrograde p-type region 162 at the principal surface 106 offset from the end 112′ of the drift region 111″ thereby leaving a channel 164 between the n-type well 163 and the end 112′ of the drift region 111″.

A gate dielectric 165 is disposed on the principal surface 106 over the channel 164. The gate dielectric 165 may comprise a layer of silicon dioxide having a thickness of, for instance, between 20 and 100 nm, such as about 60 nm, although a thinner or thicker layer may be used. The gate dielectric 165 runs between a further dielectric layer 167 which covers a channel-side portion 168 of the highly-doped n-type well 163, along the principal surface 106 and abuts the field dielectric 115 forming a step 169. A third metallization layer 170 is disposed on the gate dielectric 165 and runs over the step 169 onto the field dielectric 115 and provides a gate metallization for gating the channel 164.

A modified first metallization layer 120′ runs over the p− pillar 128 and the highly-doped n-type well 163 to provide a first contact 121′ on a p− pillar-side portion 171 of the highly-doped n-type well 163. In this case, the metallization layer 120′ does not run onto the dielectric layer 115 to form a field plate, but instead stops at the edge of the further dielectric layer 167.

In this case, the first contact window has a width we′ of 1.5 μm, the dielectric layer 167 has a width w_{fd} of 1.5 μm, the gate dielectric has a width w_{gd} of 1.5 μm, and the gate metallization overlap has a width w_{gmo} of 1.5 μm. The second field plate has a width w_{2fp} of 3 μm, and the highly-doped n-region 124 extends under the field dielectric 115 by w of 1.5 μm.

In this example, the widths w_{zone1}, w_{zone2} are 7.5 μm and 7.5 μm respectively, and the doping concentrations N_{zone1}, N_{zone2} are 3×10¹⁶ cm⁻³ and 1.5×10¹⁷ cm⁻³, respectively

### IGBT

Referring to FIG. 20, a lateral, RESURF-based SiC IGBT 181 is shown.

The IGBT 181 is the same as the MOSFET 161 (FIG. 19) hereinbefore described, but differs that the highly-doped contact region of the second conductivity type (in this case n-type) is replaced by a highly-doped contact region of first conductivity type (in this case p-type).

The n-type drift region 111″ extends beyond the end of the dielectric layer 115 and a highly doped p-type region 182 is disposed in the n-type drift region 111′″ at the principal surface 106 to provide a contact 126′ to the second metallization 125. The highly doped p-type region 182 runs from an edge 183 lying under the field plate 127. The overlap between the edge 183 and the second end 117 of the dielectric layer 115 is a width wᵣ of 1.5 μm.

### Drift Region

In the devices herein described, the drift region and the underlying epitaxial layer have a reduced surface field (RESURF) configuration to decrease the slope of the electric field distribution in the drift region parallel to the principal surface.

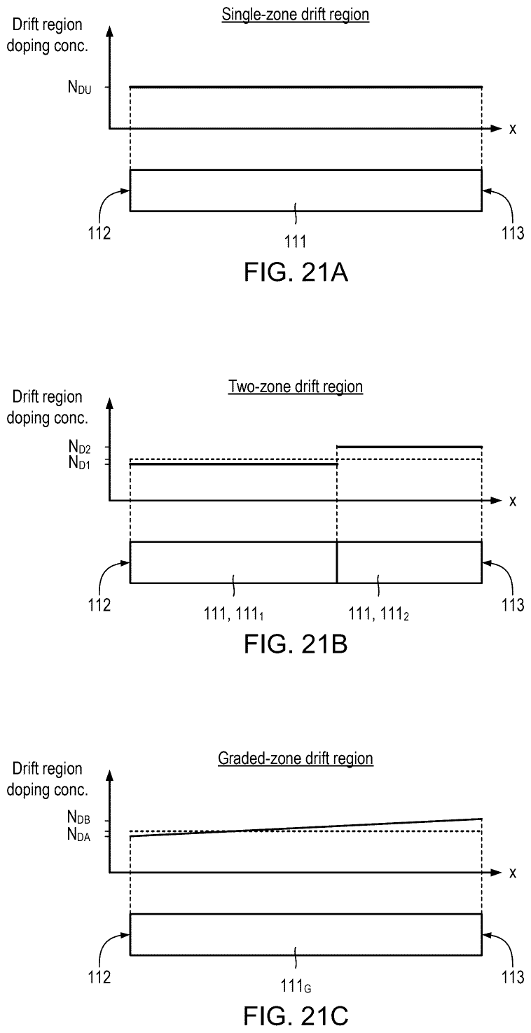

Referring to FIG. 21A, a drift region 111 may be uniformly doped (for a given thickness of drift region) to a doping density N_{DU} for achieving RESURF.

Referring to FIG. 21B, in some embodiments, a two-zone drift region 111 may be used in which the doping concentration N_{D1} in a first zone 111₁ (which is closer to the anode) is lower than the doping concentration N_{D2} in the second zone 111₂ (which is closer to the cathode), while still satisfying the requirements for achieving RESURF.

Additional zones may be included, for example, three or more zones following the same rule, namely N_{Di}<N_{D(i+1)}, where i=1, 2, etc.

Referring to FIG. 21C, a graded drift region 111 may be used in which the doping concentration increases from a first value NDA at the first end to a second value NDB at the second end, while still satisfying the requirements for achieving RESURF. Preferably, the doping concentration increases monotonically and may increase linearly.

### Fabrication

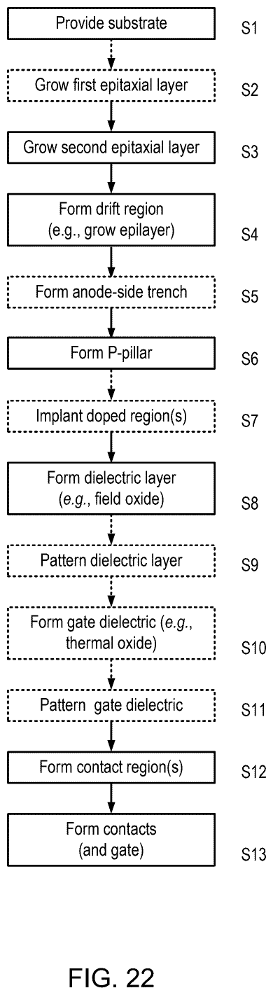

Referring to FIG. 22, a method of fabricating a lateral, RESURF-based SiC device 101, 141, 161, 181 will now be described.

A substrate 102 (FIG. 15) is provided (step S1). The substrate 102 (FIG. 15) takes the form of an n- or p-type 4H—SiC substrate. Other forms of substrate may, however, be used, such as silicon substrate. If necessary, a first epitaxial layer 103 (FIG. 15) is grown on the base substrate 102 (FIG. 15) (step S2). For example, the substrate 102 (FIG. 15) may take the form of a n-type 4H—SiC substrate and the first epitaxial layer 103 (FIG. 15) may take the form of a layer of heavily-doped p-type 4H—SiC.

A second epitaxial layer 107 (FIG. 15) is grown either on the substrate or on the first epitaxial layer 103 (FIG. 15) (step S3). The second epitaxial layer 107 (FIG. 15) may take the form of a layer of light-doped p-type 4H—SiC.

A region or layer of 4H—SiC layer (not shown) is formed, for example grown, directly on the second epitaxial layer 107 (FIG. 15) which used to provide the drift region 111 (FIG. 15) (step S4). For example, the 4H—SiC layer may take the form of a layer of lightly-doped n-type 4H—SiC.

The anode-side trench may then be formed (step S5). For example, this may comprise applying layer of photoresist (not shown) over the structure and patterning the photoresist layer to form a mask (not shown). The mask pattern is transferred to the underlying structure by dry etching.

The pillar 128 (FIG. 15) is formed by side implantation (step S6). Alternatively, a deep pillar may be formed by implantation from the principal surface (without a trench).

Further regions may be implanted, such as zonal or graded doping of the drift region 111 and contact regions 124 (FIG. 15), 128″ (FIG. 18), 163 (FIG. 19), 183 (FIG. 20) (step S7). For example, for each region, a suitable mask (not shown) is formed and suitable dopant ions (donors or acceptors) are implanted under suitable ion implantation conditions (e.g., energy, dose etc.).

The dielectric layer 115 (FIG. 15) is formed (step S8). For example, the dielectric layer 115 may take the form of a layer silicon dioxide which may be thermally grown or deposited by a suitable CVD process.

The dielectric layer 115 (FIG. 15) may be patterned (step S9) and, if required, a gate dielectric layer may be formed (step S10) and patterned (step S11). The gate dielectric may take the form of a layer silicon dioxide which may be thermally grown. Other gate dielectric materials may be used.

If not already formed, contact regions(s) 124 (FIG. 15), 128″ (FIG. 18) may be formed (step S12). For example, regions may be implanted.

Contacts are formed, in other words, metallization is formed (step S13). For example, this may comprise depositing a metalation layer, applying layer of photoresist (not shown) over the metallization and patterning the photoresist layer to form a mask (not shown). The mask pattern is transferred to the underlying metallization by dry etching to form first and second metallizations 120, 125 and, optional, third, gate metallization 170 (FIG. 19).

### Double RESURF Structure

In the examples hereinbefore described, a single RESURF structure is employed. Other RESURF structures, such as a double RESURF structure may, however, be used.

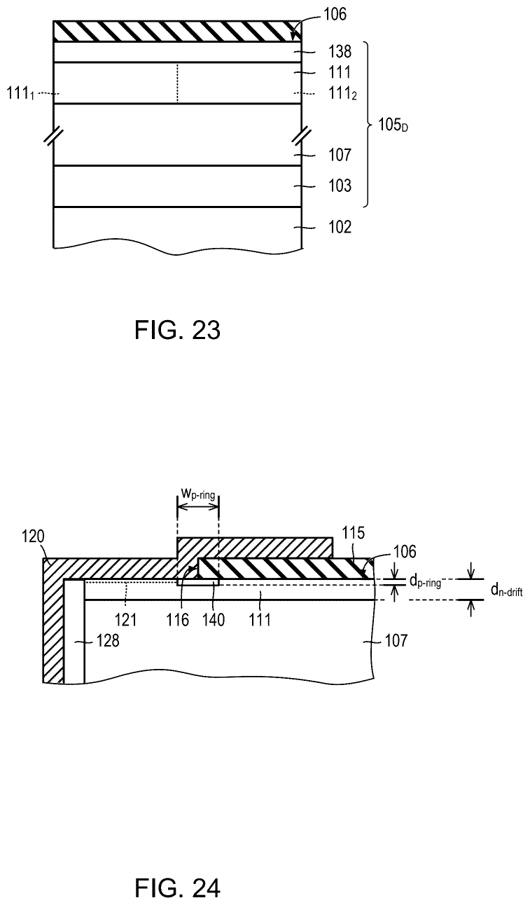

Referring to FIG. 23, a layer structure 105D in the middle of the drift region 111 is shown. The layer structure 105D is similar to the structure 105 (FIG. 15) described earlier, except that an additional region 138 (or “top region”) of the first conductivity type, in this case p-type, is disposed between the surface 106 and the drift region 111 (which is of the second conductivity type). The top region 138 may have thickness dₜₒₚ for example of between 50 to 300 nm, for example, between 100 and 200 nm and a doping concentration of about half that of the drift region 111. The top region 138 may be formed by implantation. Accordingly, the thickness of the epitaxial layer (not shown) which is grown on the underlying epitaxial layer 103 may be made thicker. For instance, if the drift layer 111 is intended to have a thickness of 500 nm and the top layer 138 is intended to have a thickness of 200 nm, then the epitaxial layer (not shown) may be grown having a thickness of 700 nm. The drift region 111 may be divided into zone 111₁, 111₂ or be graded.

### Suppressing Off-State Leakage

Referring to FIG. 24, a short, shallow doped region 140 of opposite composite type to the drift region 111, in other words of first conductivity type (in this case, p-type), may be provided at the end 116 of the dielectric layer 115 adjacent to the Schottky contact 121 at the principal surface 106. The shallow doped region 140 can help to suppress off-state leakage.

The shallow doped region 140 runs along the edge of the ring-shaped Schottky contact 121 (i.e., the anode) and so is also referred to as a “shallow doped ring” or simply “ring”. In this case, the shallow doped ring 140 is p-type and so the ring 140 is also referred to as a “p-ring”.

The p-ring 140 encircles the Schottky contact 121 with an overlap so as to control how much electric field that is seen by the Schottky contact 121 under blocking conditions. The p-ring 140 can be seen as being similar to a Junction Barrier Schottky (JBS) with the Schottky contact 121 opening determining the electric field. A high barrier height metal contact (such as titanium) can be used to help reduce leakage.

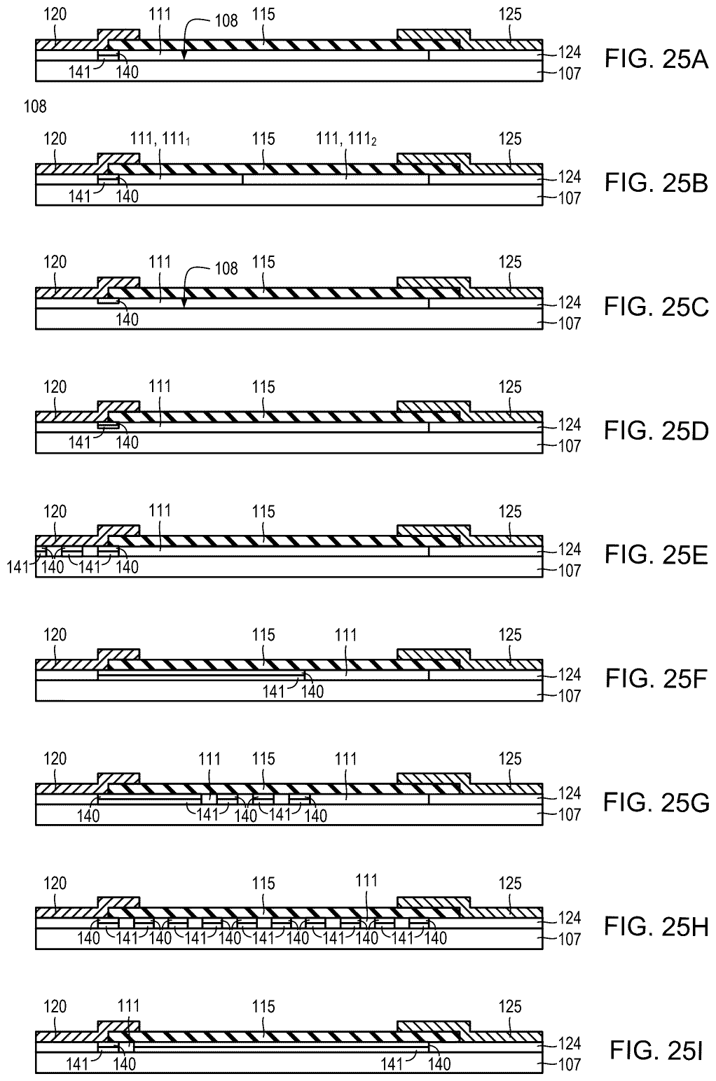

The p-ring 140 encircling the Schottky contact with an overlap extending towards the anode can be beneficial if the n-layer underlying this extension is enhanced which can help to “kill” the junction-gate field-effect transistor (JFET) and also have a super-junction (SJ) structure. This is described in more detail hereinafter with reference to FIGS. 25A to 25I.

The p-ring 140 may have a doping concentration of between 5×10¹⁷ cm⁻³ and 1×10¹⁹ cm⁻³, preferably about 1×10¹⁸ cm⁻³. The p-ring 140 has a thickness d_{p-ring} and a width w_{p-ring}. The p-ring depth d_{p-ring} may be between 10% and 50% of the thickness d_{n-drift} of the drift region 111, i.e., 0.1 d_{n-drift}≤d_{p-ring}≤0.5 d_{n-drift}, and is preferably between 15% and 25% of the thickness d_{n-drift} of the drift region 111, i.e., 0.15 d_{n-drift}<d_{p-ring}≤0.25 d_{n-drift}. For instance, in the case that the drift region thickness d_{n-drift} is 0.5 μm, then the p-ring depth d_{p-ring} may be between 50 nm and 250 nm, preferably around 100 nm. The p-ring width w_{p-ring} may be up to half the width w_{n-drift} of the drift region 111 and may be, for example, 100 nm≤w_{p-ring}≤5 μm.

An off-state leakage suppressing ring 140 can be incorporated into the RESURF-based SiC devices hereinbefore described, such as device 31 (FIG. 9), device 101 (FIG. 15), 141, (FIG. 18), device 161 (FIG. 19) and device 181 (FIG. 20), in several different ways.

FIGS. 25A to 25I illustrate RESURF-based SiC devices which each include an epitaxial layer 107, a drift region 111, a dielectric layer 115, a metallization contact layer 120 (which forms the Schottky barrier), a contact region 124, and a second metallization layer 125. The highly-doped pillar 128 is omitted for clarity.

Referring to FIG. 25A, the device may include a buried doped region 141 (or “implanted region”) under the shallow doped region 140 which is of the same conductivity type of the drift region 111 and opposite conductivity type of the shallow doped region 140. Thus, in the case of a p-type ring, the buried doped region 141 is an n-type ring 141. The p- and n-type regions 140, 141 may be coterminous (in plan view). The p- and n-type regions 140, 141 can create a double RESURF/SJ effect. The buried doped region 141 may have a doping concentration of between 1×10¹⁷ cm⁻³ and 1×10¹⁹ cm⁻³. The buried doped region 141 can have a thickness of at least 50 nm and can extend to the bottom of the drift region 111, i.e., to the upper surface 108 of the epilayer 107.

The addition of the implanted region 141 can help suppress leakage by preventing the highest electric field reach the anode Schottky metal 120.

Referring also to FIG. 25B, the implanted region 141 can be used in a two-zone drift region 111₁, 111₂. The addition of the implanted region 141 allows the first zone 111₁ (which is the closer of the two zones to the anode) to be doped more highly, thereby helping to lower resistance.

Referring to FIG. 25C, the shallow doped region 140 can be used without the underlying implanted region 141 (FIG. 25A).

Referring to FIG. 25D, the two regions 140, 141 can be thinner. In particular, the regions 140, 141 need not extend as far as the upper surface 108 of the epilayer 107.

Referring to FIG. 25E, multiple off-state leakage suppressing rings 1401, 1402, 1403, with or without underlying implanted regions 1411, 1412, 1413, may be used laterally spaced apart along the width of the Schottky contact 121 (FIG. 24) similar to multiple vertical JBS diodes.

In the devices illustrated in FIGS. 25A to 25E, the off-state leakage suppressing ring 140, with or without the underlying implanted region 141, can be narrow compared to the length of the drift region 111, for example, having a width w_{p-ring} between 100 nm and 5 μm, preferably 3 μm, and is arranged such that it straddles each side of oxide-metal interface equally, for example by 1.5 μm on each side in the case that width w_{p-ring} is 3 μm.

Referring to FIG. 25F, the off-state leakage suppressing ring 140, with or without the underlying implanted region 141, can extend though the majority of drift region 111 creating a double RESURF SJ, for example, w_{p-ring}≥5 μm.

Referring to FIGS. 25G to 25I, combinations of extended off-state leakage suppressing ring 140 and multiple off-state leakage suppressing rings 140 in the drift region 111 hereinbefore described can be used.

### Modifications

It will be appreciated that various modifications may be made to the embodiments hereinbefore described. Such modifications may involve equivalent and other features which are already known in the design, manufacture and use of silicon carbide semiconductor devices and component parts thereof and which may be used instead of or in addition to features already described herein. Features of one embodiment may be replaced or supplemented by features of another embodiment.

The drift layer may be p-type. Thus, the underlying epitaxial layer may be n-type and the pillar may be heavily doped n-type.

3-step cubic silicon carbide (3C—SiC) may be used instead of 4H—SiC. Dielectrics such as silicon nitride, silicon oxynitride or high-k dielectrics may be used. Metallizations may comprise titanium, molybdenum, aluminium, silicon silicide or titanium nitride.

The semiconductor device may include a triple RESURF structure.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A lateral silicon carbide power semiconductor device, comprising:
a substrate;
a silicon carbide semiconductor structure disposed on the substrate and having a principal surface, the semiconductor structure comprising:
a layer of first conductivity type disposed on the substrate; and
a layer-shaped drift region of a second conductivity type, which is opposite to the first conductivity type, disposed directly on the layer so as to form an interface between the layer and the drift region, the drift region running laterally along the principal surface between first and second ends, wherein doping in the drift region and the layer are arranged so as to deplete the drift region;
a first contact region to the first end of the drift region;
a second contact region to the second end of the drift region which is highly doped, which is of the first or second conductivity type, and which adjoins the second end of the drift region, is disposed in the drift region or is disposed in a region adjoining the second end of the drift region; and
a highly-doped region of the first conductivity type extending into the semiconductor structure from the principal surface and adjoining the first end of the drift region, wherein the highly-doped region has a thickness greater than the drift region.

2. The lateral silicon carbide power semiconductor device of claim 1, wherein the layer-shaped drift region comprises at least first and second zones between the first and second ends of the drift region, wherein a doping concentration in the first region is lower than the doping concentration in the second region.

3. The lateral silicon carbide power semiconductor device of claim 1, wherein the layer-shaped drift region has a doping profile such that the doping concentration increases between the first and second ends of the drift region.

4. The lateral silicon carbide power semiconductor device of claim 1, wherein the drift region has a thickness of between 0.1 and 10 μm, between 0.1 and 2 μm, or between 0.2 and 0.8 μm.

5. The lateral silicon carbide power semiconductor device of claim 1, wherein the drift region has a length between the first and second ends of between 2 and 35 μm or between 5 and 20 μm.

6. The lateral silicon carbide power semiconductor device of claim 1, wherein the drift region has doping concentration(s) between 5×10¹⁵ cm⁻³ and 1×10¹⁸ cm⁻³ or between 1×10¹⁶ cm⁻³ and 5×10¹⁷ cm⁻³.

7. The lateral silicon carbide power semiconductor device of claim 1, wherein the highly-doped region extends a distance Δ below the interface between the layer and the drift region of between 0.1 and 10 μm.

8. The lateral silicon carbide power semiconductor device of claim 1, wherein the highly-doped region has a doping concentration of at least 1×10¹⁸ cm⁻³.

9. The lateral silicon carbide power semiconductor device of claim 1, wherein the first conductivity type is p-type and the second conductivity type is n-type.

10. The lateral silicon carbide power semiconductor device of claim 1, further comprising:
a dielectric layer disposed on the drift region having first and second ends, the dielectric layer partially covering the drift region.

11. The lateral silicon carbide power semiconductor device of claim 10, further comprising:
first terminal or first metallization layer arranged to contact the first contact region.

12. The lateral silicon carbide power semiconductor device of claim 11, further comprising:
a doped region of a first conductivity type at the end of the dielectric layer at the principal surface for helping to suppress off-state leakage.

13. The lateral silicon carbide power semiconductor device of claim 12, further comprising:
a further doped region of a second conductivity type underlying and in direct contact with the doped region forming a double RESURF structure.

14. The lateral silicon carbide power semiconductor device of claim 1, further comprising:
second terminal or second metallization layer arranged to contact the second contact region.

15. The lateral silicon carbide power semiconductor device of claim 1, further comprising:
a further layer-shaped region of a first conductivity type disposed directly on the drift region.

16. The lateral silicon carbide power semiconductor device of claim 1, which has a breakdown voltage of between 400 and 1000 V.

17. The lateral silicon carbide power semiconductor device of claim 16, wherein doping in the drift region is constant between the first and second ends.

18. The lateral silicon carbide power semiconductor device of claim 1, which has a breakdown voltage of between 1000 and 1400 V.

19. The lateral silicon carbide power semiconductor device of claim 1, which has a breakdown voltage of between 1400 and 4000 V.

20. The lateral silicon carbide power semiconductor device of claim 16, wherein the layer-shaped drift region comprises at least first and second zones between the first and second ends of the drift region, wherein the doping concentration in the first region is lower than the doping concentration in the second region or the layer-shaped drift region has a doping profile such that the doping concentration increases between the first and second ends of the drift region.

21. The lateral silicon carbide power semiconductor device of claim 1, which is configured to be a Schottky barrier diode.

22. The lateral silicon carbide power semiconductor device of claim 1, which is configured to be a PiN diode, MOSFET or IGBT.

23. (canceled)

24. (canceled)

25. A monolithic semiconductor device comprising a plurality of the lateral silicon carbide power semiconductor devices of claim 1.

26. A vehicle or instrumentation comprising the lateral silicon carbide power semiconductor device of claim 1.

27. A method of operating the lateral silicon carbide power semiconductor device of claim 1, the method comprising:
causing placement of the lateral silicon carbide power semiconductor device in an environment subject to ionizing radiation, heavy-ion irradiation and/or proton irradiation; and
applying a bias of at least 400 v, at least 650V, at least 1200V, or at least 2000V across the drift region.
